(19) United States
(12) Patent Application Publication
(10) Pub. No.: US 2016/0011509 A1
(43) Pub. Date: Jan. 14, 2016

(54) PHOTOSENSITIVE RESIN COMPOSITION FOR BLACK MATRIX, BLACK MATRIX, COLOR FILTER AND METHOD FOR MANUFACTURING THE SAME, AND LIQUID CRYSTAL DISPLAY APPARATUS

(71) Applicant: Chi Mei Corporation, Tainan City (TW)

(72) Inventors: Hao-Wei Liao, Kaohsiung City (TW); Hung-Chia Chou, Kaohsiung City (TW)

(21) Appl. No.: 14/864,909

(22) Filed: Sep. 25, 2015

Related U.S. Application Data
(63) Continuation-in-part of application No. 14/614,377, filed on Feb. 4, 2015.

(30) Foreign Application Priority Data
Feb. 13, 2014 (TW) 103104745
Oct. 1, 2014 (TW) 103134200

(51) Int. Cl. G03F 7/038; G02B 5/22; G03F 7/00

(52) U.S. Cl. CPC G03F 7/0388; G03F 7/0007; G02B 5/223

(57) ABSTRACT

A photosensitive resin composition capable of forming a black matrix having good adhesion and good hardness, a black matrix, a color filter and a method for manufacturing the same, and a liquid crystal display apparatus are provided. The photosensitive resin composition includes an alkali-soluble resin (A), a compound (B) having an ethylenically unsaturated group, a photoinitiator (C), a hyperbranched polymer (D), a solvent (E), and a black pigment (F). The alkali-soluble resin (A) includes a first alkali-soluble resin (A-1) represented by formula (1). The hyperbranched polymer (D) is formed by reacting a multi-mercapto compound and a multi-functional (meth)acrylate.

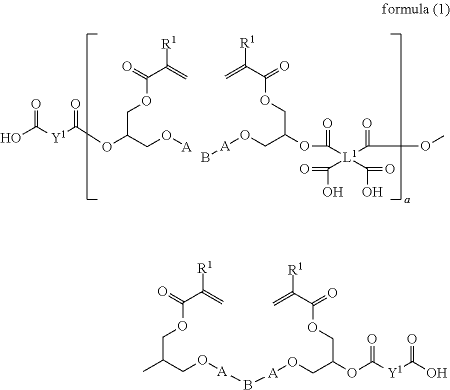

### CROSS-REFERENCE TO RELATED APPLICATION

This application is a continuation-in-part of a prior U.S. patent application Ser. No. 14/614,377, filed on Feb. 4, 2015, now pending, which claims the priority benefit of Taiwan application serial no. 103104745, filed on Feb. 13, 2014. This application also claims the priority benefit of Taiwan application serial no. 103134200, filed on Oct. 1, 2014. The entirety of each of the above-mentioned patent applications is hereby incorporated by reference herein and made a part of this specification.

### BACKGROUND OF THE INVENTION

1. Field of the Invention

The invention relates to a photosensitive resin composition for a black matrix, a black matrix, a color filter and a method for manufacturing the same, and a liquid crystal display apparatus, more particularly, to a photosensitive resin composition for a black matrix capable of forming a black matrix having good adhesion and good hardness, a black matrix formed by the photosensitive resin composition for a black matrix, a color filter having the black matrix and a method for manufacturing the same, and a liquid crystal display apparatus including the color filter.

2. Description of Related Art

Recently, with the development of various liquid crystal display (LCD) apparatus techniques, to increase the contrast and the display quality of the current LCD apparatus, a black matrix is generally disposed in the gap of the stripes and the dots of the color filter in the LCD apparatus. The black matrix can prevent issues such as decrease in contract ratio and decrease in color purity caused by light leakage between pixels.

The material used by the black matrix is generally an evaporated film containing chromium or chromium oxide. However, when using the evaporated film as the material of the black matrix, disadvantages such as complex process and expensive material exist. To solve the issues, a method for forming a black matrix by using a photosensitive resin composition through photo lithography has previously been proposed.

With the rising demand for the light-shielding property of the black matrix, one of the solutions has been increasing the usage amount of the black pigment to increase the light-shielding property of the black matrix. For instance, JP 2006-259716 discloses a photosensitive resin composition for a black matrix containing a high usage amount of each of a black pigment, an alkali-soluble resin, a photopolymerization initiator, a reactive monomer having a difunctional group, and an organic solvent. It should be mentioned that, the reactive monomer having a difunctional group can improve the reaction between compounds to form a fine pattern. As a result, when increasing the light-shielding property in the photosensitive resin composition by increasing the usage amount of the black pigment, the sensitivity of the photosensitive resin composition can still be maintained.

Moreover, JP 2008-268854 discloses a photosensitive resin composition for a black matrix. The photosensitive resin composition contains an alkali-soluble resin having a carboxylic acid group and an unsaturated group, a photopolymerizable monomer having an ethylenically unsaturated group, a photopolymerization initiator, and a black pigment with a high usage amount. In the photosensitive resin composition for a black matrix, a specific alkali-soluble resin is used to improve the resolution of the photosensitive resin composition having a high usage amount of black pigment.

The current techniques can increase the light-shielding property of the photosensitive resin composition by increasing the usage amount of the black pigment. However, the adhesion and the hardness of the black matrix formed by the known photosensitive resin composition are poor.

Therefore, how to provide a photosensitive resin composition for a black matrix capable of forming a black matrix having both good adhesion and hardness is a current issue those skilled in the art urgently need to solve.

### SUMMARY OF THE INVENTION

Accordingly, the invention provides a photosensitive resin composition for a black matrix of a liquid crystal display apparatus. The photosensitive resin composition can alleviate the issue of poor adhesion and hardness of the black matrix.

The invention provides a photosensitive resin composition for a black matrix including an alkali-soluble resin (A), a compound (B) having an ethylenically unsaturated group, a photoinitiator (C), a hyperbranched polymer (D), a solvent (E), and a black pigment (F).

Specifically, the alkali-soluble resin (A) includes a first alkali-soluble resin (A-1) represented by formula (1).

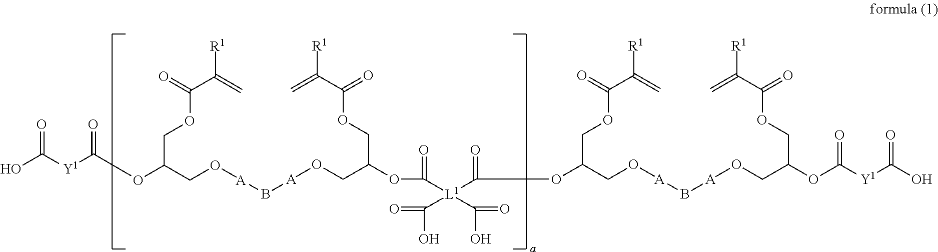

In formula (1), A represents a phenylene group or a phenylene group having a substituent, wherein the substituent is a C₁ to C₅ alkyl group, a halogen atom, or a phenyl group; B represents —CO—, —SO₂—, —C(CF₃)₂—, —Si(CH₃)₂—, —CH₂—, —C(CH₃)₂—, —O—, 9,9-fluorenylidene, or a single bond; L¹ represents a tetravalent carboxylic acid residue containing a fluorine atom or a tetravalent carboxylic acid residue without a fluorine atom; Y¹ represents a divalent carboxylic acid residue containing a fluorine atom or a divalent carboxylic acid residue without a fluorine atom; R¹ represents a hydrogen atom or a methyl group; a represents an integer of 1 to 20; and at least one of L′ and Y′ contains a fluorine atom.

The hyperbranched polymer (D) is formed by reacting a multi-mercapto compound represented by formula (II) and a multi-functional (meth)acrylate represented by formula (I).

Specifically, the multi-functional (meth)acrylate represented by formula (I) is as shown below.

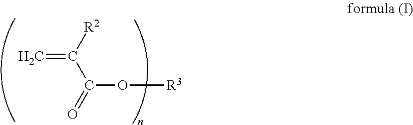

In formula (I), R² represents a hydrogen atom or a C₁ to C₄ alkyl group;

R³ represents a residual group after the esterification of an n number of hydroxyl groups in a hydroxyl group-containing compound having an m number of hydroxyl groups, wherein m≧n, and n represents an integer of 2 to 20,

the hydroxyl group-containing compound is R⁴(OH)ₘ or a compound in which the R⁴(OH)ₘ is modified by propylene oxide, epichlorohydrin, an alkyl group, an alkoxy group, or hydroxypropyl acrylate,

R⁴(OH)ₘ is a C₂ to C₁₈ polyalcohol, polyhydric alcohol ether formed by the polyalcohol, an ester formed by reacting the polyalcohol and an acid, or silicone.

The multi-mercapto compound represented by formula (II) is as shown below.

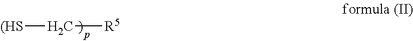

In formula (II), R⁵ represents a single bond, a C₁ hydrocarbon group, or a C₂ to C₂₂ straight-chain or branched-chain hydrocarbon group, and a skeleton of R⁵ may further include a sulfur atom or an oxygen atom formed in an ester group,

p represents an integer of 2 to 6, wherein in the case that R⁵ represents a single bond, p represents 2; in the case that R⁵ represents a C₁ hydrocarbon group, p represents an integer of 2 to 4; and in the case that R⁵ represents a C₂ to C₂₂ straight-chain or branched-chain hydrocarbon group, p represents an integer of 2 to 6.

In an embodiment of the invention, in the hyperbranched polymer (D), an addition molar ratio of a mercapto group of the multi-mercapto compound represented by formula (II) with respect to a carbon-carbon double bond of the multi-functional (meth)acrylate represented by formula (I) is 1/200 to 1/2.

In an embodiment of the invention, the hyperbranched polymer (D) is formed by reacting a remaining (meth)acrylate group from a reaction of the multi-mercapto compound represented by formula (II) and the multi-functional (meth)acrylate represented by formula (I) with a mercapto compound having a carboxyl group represented by formula (III).

HS—R⁶COOH)_{q} formula (III)

In formula (III), R⁶ represents a C₁ to C₁₂ alkylene group and q represents an integer of 1 to 3.

In an embodiment of the invention, in the hyperbranched polymer (D), an addition molar ratio of a mercapto group of the multi-mercapto compound represented by formula (II) and the mercapto compound having a carboxyl group represented by formula (III) with respect to a carbon-carbon double bond of the multi-functional (meth)acrylate represented by formula (I) is 1/200 to 1/2.

In an embodiment of the invention, the alkali-soluble resin (A-1) is obtained by reacting a first mixture, and the first mixture includes a diol compound (a-1) containing a polymeric unsaturated group, a tetracarboxylic acid or an acid dianhydride thereof (a-2), and a dicarboxylic acid or an acid anhydride thereof (a-3). The tetracarboxylic acid or an acid dianhydride thereof (a-2) includes a tetracarboxylic acid or an acid dianhydride thereof (a-2-1) containing a fluorine atom, other tetracarboxylic acids or an acid dianhydride thereof (a-2-2) other than the tetracarboxylic acid or an acid dianhydride thereof (a-2-1) containing a fluorine atom, or a combination of the two. The dicarboxylic acid or an acid anhydride thereof (a-3) includes a dicarboxylic acid or an acid anhydride thereof (a-3-1) containing a fluorine atom, other dicarboxylic acid anhydrides or a dicarboxylic acid compound thereof (a-3-2) other than the dicarboxylic acid or an acid anhydride thereof (a-3-1) containing a fluorine atom, or a combination of the two. It should be mentioned that, at least one of the tetracarboxylic acid or an acid dianhydride thereof (a-2) and the dicarboxylic acid or an acid anhydride thereof (a-3) contains a fluorine atom.

In an embodiment of the invention, the tetracarboxylic acid or an acid dianhydride thereof (a-2-1) containing a fluorine atom is selected from the group consisting of a tetracarboxylic acid compound containing a fluorine atom represented by formula (2-1) and a tetracarboxylic acid dianhydride compound containing a fluorine atom represented by formula (2-2). In particular, the tetracarboxylic acid compound containing a fluorine atom represented by formula (2-1) and the tetracarboxylic acid dianhydride compound containing a fluorine atom represented by formula (2-2) are as shown below.

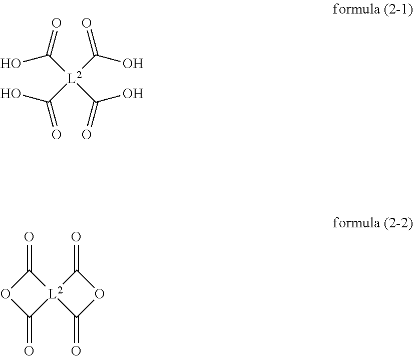

In formula (2-1) and formula (2-2), L² is selected from one of the groups represented by formula (L-1) to formula (L-6).

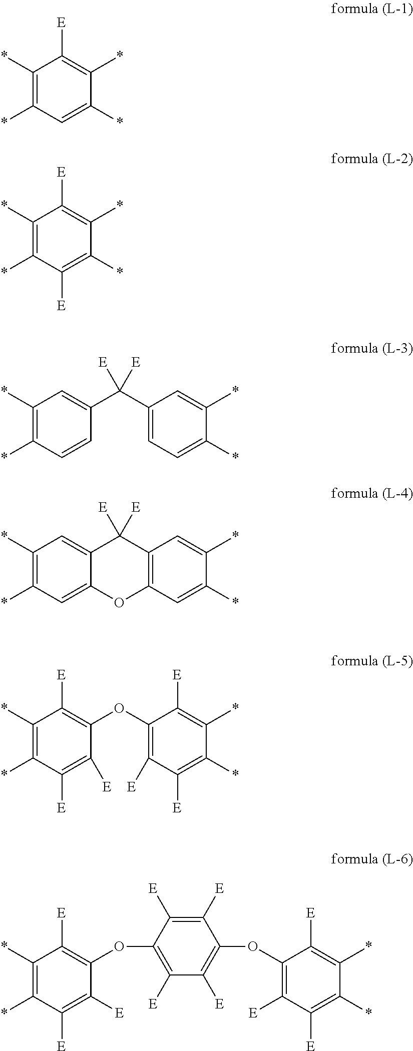

In formula (L-1) to formula (L-6), E each independently represents a fluorine atom or a trifluoromethyl group, and * represents the location of bonding with a carbon atom.

In an embodiment of the invention, the dicarboxylic acid or an acid anhydride thereof (a-3-1) containing a fluorine atom is selected from the group consisting of a dicarboxylic acid compound containing a fluorine atom represented by formula (3-1) and a dicarboxylic acid anhydride compound containing a fluorine atom represented by formula (3-2). In particular, the dicarboxylic acid compound containing a fluorine atom represented by formula (3-1) and the dicarboxylic acid anhydride compound containing a fluorine atom represented by formula (3-2) are as shown below.

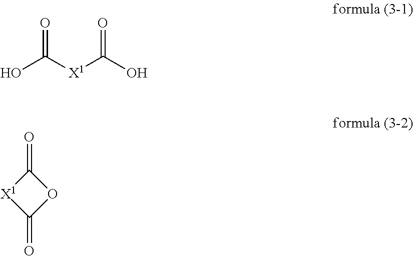

In formula (3-1) and formula (3-2), X¹ represents a C₁ to C₁₀₀ organic group containing a fluorine atom.

In an embodiment of the invention, the number of moles of the diol compound (a-1) containing a polymeric unsaturated group, the number of moles of the tetracarboxylic acid or an acid dianhydride thereof (a-2-1) containing a fluorine atom, and the number of moles of the dicarboxylic acid or an acid anhydride thereof (a-3-1) containing a fluorine atom satisfy the relationship [(a-2-1)+(a-3-1)]/(a-1)=0.4-1.6.

In an embodiment of the invention, based on a usage amount of 100 parts by weight of the alkali-soluble resin (A), the usage amount of the first alkali-soluble resin (A-1) is 10 parts by weight to 100 parts by weight, the usage amount of the compound (B) having an ethylenically unsaturated group is 15 parts by weight to 200 parts by weight, the usage amount of the photoinitiator (C) is 5 parts by weight to 55 parts by weight, the usage amount of the hyperbranched polymer (D) is 3 parts by weight to 35 parts by weight, the usage amount of the solvent (E) is 1000 parts by weight to 5000 parts by weight, and the usage amount of the black pigment (F) is 60 parts by weight to 600 parts by weight.

In an embodiment of the invention, the compound (B) having an ethylenically unsaturated group includes a compound (B-1) having an acidic group and at least three ethylenically unsaturated groups.

In an embodiment of the invention, based on a usage amount of 100 parts by weight of the alkali-soluble resin (A), the usage amount of the compound (B-1) having an acidic group and at least three ethylenically unsaturated groups is 15 parts by weight to 150 parts by weight.

The invention further provides a method for manufacturing a color filter. The method includes forming a black matrix by using the photosensitive resin composition for a black matrix.

The invention further provides a black matrix. The black matrix is formed by the photosensitive resin composition for a black matrix.

The invention also provides a color filter. The color filter includes the black matrix.

The invention further provides a liquid crystal display apparatus. The liquid crystal display apparatus includes the color filter.

Based on the above, since the photosensitive resin composition for a black matrix of the invention contains an alkali-soluble resin having an aromatic structure having fluorine and a specific structure and the hyperbranched polymer (D), the issue of poor adhesion and hardness of the black matrix can be alleviated such that the black matrix is suitable for a color filter and a liquid crystal display apparatus.

To make the above features and advantages of the invention more comprehensible, several embodiments are described in detail as follows.

### DESCRIPTION OF THE EMBODIMENTS

In the following, (meth)acrylic acid represents acrylic acid and/or methacrylic acid, and (meth)acrylate represents acrylate and/or methacrylate. Similarly, (meth)acryloyl group represents acryloyl group and/or methacryloyl group.

### <Photosensitive Resin Composition for Black Matrix>

The invention provides a photosensitive resin composition for a black matrix (also referred to as “photosensitive resin composition” herein) including an alkali-soluble resin (A), a compound (B) having an ethylenically unsaturated group, a photoinitiator (C), a hyperbranched polymer (D), a solvent (E), and a black pigment (F). Moreover, the photosensitive resin composition can further include an additive (G) if needed. In the following, the individual components used in the photosensitive resin composition of the invention are described in detail.

### Alkali-Soluble Resin (A)

The alkali-soluble resin (A) includes a first alkali-soluble resin (A-1). Moreover, the alkali-soluble resin (A) can optionally include a second alkali-soluble resin (A-2) and other alkali-soluble resins (A-3).

### First Alkali-Soluble Resin (A-1)

The first alkali-soluble resin (A-1) is a compound represented by formula 1:

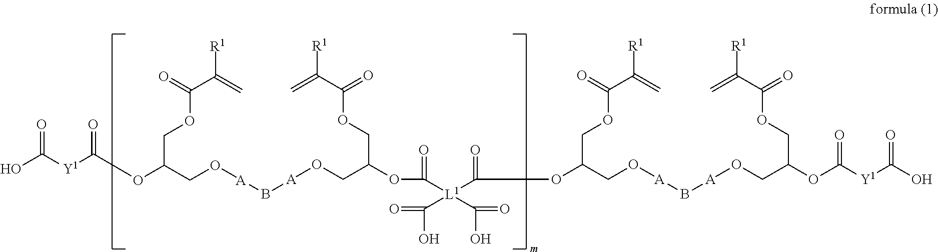

In formula (1), A represents a phenylene group or a phenylene group having a substituent, wherein the substituent is a C₁ to C₅ alkyl group, a halogen atom, or a phenyl group; B represents —CO—, —SO₂—, —C(CF₃)₂—, —Si(CH₃)₂—, —CH₂—, —C(CH₃)₂—, —O—, 9,9-fluorenylidene, or a single bond; L¹ represents a tetravalent carboxylic acid residue containing a fluorine atom or a tetravalent carboxylic acid residue without a fluorine atom; Y¹ represents a divalent carboxylic acid residue containing a fluorine atom or a divalent carboxylic acid residue without a fluorine atom; R¹ represents a hydrogen atom or a methyl group; m represents an integer of 1 to 20; and at least one of L¹ and Y¹ contains a fluorine atom.

It should be mentioned that, L¹ can be a tetravalent carboxylic acid residue containing a fluorine atom or a tetravalent carboxylic acid residue without a fluorine atom, and is preferably a tetravalent aromatic group having fluorine, more preferably a benzene ring having fluorine.

Specifically, the alkali-soluble resin (A-1) is obtained by reacting a first mixture. The first mixture includes a diol compound (a-1) containing a polymeric unsaturated group, a tetracarboxylic acid or an acid dianhydride thereof (a-2), and a dicarboxylic acid or an acid anhydride thereof (a-3). At least one of the tetracarboxylic acid or an acid dianhydride thereof (a-2) and the dicarboxylic acid or an acid anhydride thereof (a-3) needs to contain a fluorine atom. Each component of the first mixture is described below.

Diol Compound (a-1) Containing a Polymeric Unsaturated Group

The diol compound (a-1) containing a polymeric unsaturated group is obtained by reacting a bisphenol compound (a-1-i) having two epoxy groups and a compound (a-1-ii) having at least one carboxylic acid group and at least one ethylenically unsaturated group. The reactants used to synthesize the diol compound (a-1) containing a polymeric unsaturated group can also contain other compounds.

The bisphenol compound (a-1-i) having two epoxy groups can, for instance, be obtained by reacting a bisphenol compound and an epihalohydrin in a dehydrohalogenation reaction under the existence of an alkali metal hydroxide.

Specific examples of the bisphenol used to synthesize the bisphenol compound (a-1-i) having two epoxy groups include, for instance, bis(4-hydroxyphenyl)ketone, bis(4-hydroxy-3,5-dimethylphenyl)ketone, bis(4-hydroxy-3,5-dichlorophenyl)ketone, bis(4-hydroxyphenyl)sulfone, bis(4-hydroxy-3,5-dimethylphenyl)sulfone, bis(4-hydroxy-3,5-dichlorophenyl)sulfone, bis(4-hydroxyphenyl)hexafluoropropane, bis(4-hydroxy-3,5-dimethylphenyl)hexafluoropropane, bis(4-hydroxy-3,5-dichlorophenyl)hexafluoropropane, bis(4-hydroxyphenyl)dimethylsilane, bis(4-hydroxy-3,5-dimethylphenyl)dimethylsilane, bis(4-hydroxy-3,5-dichlorophenyl)dimethylsilane, bis(4-hydroxyphenyl)methane, bis(4-hydroxy-3,5-dichlorophenyl)methane, bis(4-hydroxy-3,5-dibromophenyl)methane, 2,2-bis(4-hydroxyphenyl)propane, 2,2-bis(4-hydroxy-3,5-dimethylphenyl)propane, 2,2-bis(4-hydroxy-3,5-dichlorophenyl)propane, 2,2-bis(4-hydroxy-3-methylphenyl)propane, 2,2-bis(4-hydroxy-3-chlorophenyl)propane, bis(4-hydroxyphenyl)ether, bis(4-hydroxy-3,5-dimethylphenyl)ether, or bis(4-hydroxy-3,5-dichlorophenyl)ether; 9,9-bis(4-hydroxyphenyl)fluorene, 9,9-bis(4-hydroxy-3-dimethylphenyl)fluorene, 9,9-bis(4-hydroxy-3-chlorophenyl)fluorene, 9,9-bis(4-hydroxy-3-bromophenyl)fluorene, 9,9-bis(4-hydroxy-3-fluorophenyl)fluorene, 9,9-bis(4-hydroxy-3,5-dimethylphenyl)fluorene, or a combination of the compounds.

Specific examples of the epihalohydrin used to synthesize the bisphenol compound (a-1-i) having two epoxy groups include 3-chloro-1,2-epoxypropane (epichlorohydrin), 3-bromo-1,2-epoxypropane (epibromohydrin), or a combination of the compounds. Based on a total equivalent of 1 equivalent of the hydroxyl group in the bisphenol compound, the usage amount of the epihalohydrin can be 1 equivalent to 20 equivalents, preferably 2 equivalents to 10 equivalents.

Specific examples of the alkali metal hydroxide include sodium hydroxide, potassium hydroxide, or a combination of the compounds. Based on a total equivalent of 1 equivalent of the hydroxyl group in the bisphenol compound, the usage amount of the alkali metal hydroxide added in the dehydrohalogenation reaction can be 0.8 equivalents to 15 equivalents, preferably 0.9 equivalents to 11 equivalents.

It should be mentioned that, before the dehydrohalogenation reaction is performed, an alkali metal hydroxide such as sodium hydroxide or potassium hydroxide can be pre-added or added during the reaction process. The operating temperature of the dehydrohalogenation reaction is 20° C. to 120° C. and the operating time thereof ranges from 1 hour to 10 hours.

In an embodiment, the alkali metal hydroxide added to the dehydrohalogenation reaction can also be an aqueous solution thereof. In the present embodiment, when an aqueous solution of the alkali metal hydroxide is continuously added in the dehydrohalogenation reaction system, water and epihalohydrin can be continuously distilled off under reduced pressure or atmospheric pressure at the same time to separate and remove water, and epihalohydrin can be continuously flown back to the reaction system at the same time.

Before the dehydrohalogenation reaction is performed, a quaternary ammonium salt such as tetramethyl ammonium chloride, tetramethyl ammonium bromide, or trimethylbenzyl ammonium chloride can also be added as a catalyst. Then, at 50° C. to 150° C., the mixture is reacted for 1 hour to 5 hours, and then the alkali metal hydroxide or an aqueous solution thereof is added. Then, the mixture is reacted at a temperature of 20° C. to 120° C. for 1 hour to 10 hours to perform the dehydrohalogenation reaction.

Moreover, to facilitate the dehydrohalogenation reaction, in addition to adding an alcohol such as methanol or ethanol, an aprotic polar solvent such as dimethyl sulfone or dimethyl sulfoxide can also be added to perform the reaction. In the case that an alcohol is used, based on a total amount of 100 wt % of the epihalohydrin, the usage amount of the alcohol can be 2 wt % to 20 wt %, preferably 4 wt % to 15 wt %. In the case that an aprotic polar solvent is used, based on a total amount of 100 wt % of the epihalohydrin, the usage amount of the aprotic polar solvent can be 5 wt % to 100 wt %, preferably 10 wt % to 90 wt %.

After the dehydrohalogenation reaction is complete, a rinse treatment can be optionally performed. Then, the epihalohydrin, the alcohol, and the aprotic polar solvent . . . etc. are removed by using a method of heating under reduced pressure, such as at a temperature of 110° C. to 250° C. and a pressure of 1.3 kPa (O1 mmHg).

To prevent the epoxy resin formed from containing a hydrolyzable halogen, the solution after the dehydrohalogenation reaction can be added to a solvent such as benzene, toluene, or methyl isobutyl ketone, and then an aqueous solution of an alkali metal hydroxide such as sodium hydroxide or potassium hydroxide can be added to perform the dehydrohalogenation reaction again. In the dehydrohalogenation reaction, based on a total equivalent of 1 equivalent of the hydroxyl group in the bisphenol compound, the usage amount of the alkali metal hydroxide can be 0.01 moles to 1 mole, preferably 0.05 moles to 0.9 moles. Moreover, the operating temperature of the dehydrohalogenation reaction ranges from 50° C. to 120° C. and the operating time thereof ranges from 0.5 hours to 2 hours.

After the dehydrohalogenation reaction is complete, the salt is removed through steps such as filtering and rinsing. Moreover, solvents such as benzene, toluene, and methyl isobutyl ketone can be distilled off by a method of heating under reduced pressure to obtain the bisphenol compound (a-1-i) having two epoxy groups.

The bisphenol compound (a-1-i) having two epoxy groups is preferably a bisphenol compound having two epoxy groups represented by formula (1-1) or a polymer formed by polymerizing a bisphenol compound having two epoxy groups represented by formula (1-2) as a monomer.

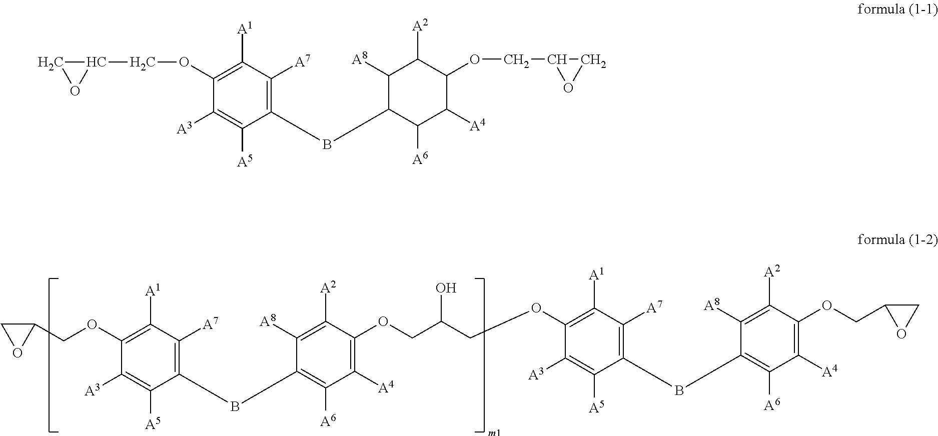

In formula (1-1) and formula (1-2), A¹ to A⁸ each independently represent a hydrogen atom, a halogen atom, a C₁ to C₅ alkyl group, or a phenyl group. B represents —CO—, —SO₂—, —C(CF₃)₂—, —Si(CH₃)₂—, —CH₂—, —C(CH₃)₂—, —O—, 9,9-fluorenylidene, or a single bond. m1 can represent an integer of 1 to 10, and ml preferably represents an integer of 1 to 2.

The bisphenol compound having two epoxy groups represented by formula (1-1) is preferably a bisphenol compound having two epoxy groups represented by formula (1-3).

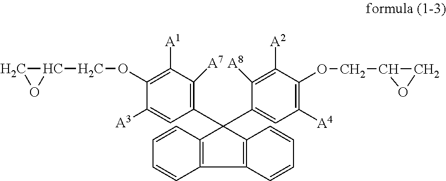

In formula (1-3), A¹, A², A³, A⁴, A⁷, and A⁸ each independently represent a hydrogen atom, a halogen atom, a C₁ to C₅ alkyl group, or a phenyl group.

The bisphenol compound having two epoxy groups represented by formula (1-3) is, for instance, a bisphenol fluorene-type compound having two epoxy groups obtained by reacting a bisphenol fluorene compound and an epihalohydrin.

Specific examples of the bisphenol fluorene-type compound include 9,9-bis(4-hydroxyphenyl)fluorene, 9,9-bis(4-hydroxy-3-methylphenyl)fluorene, 9,9-bis(4-hydroxy-3-chlorophenyl)fluorene, 9,9-bis(4-hydroxy-3-bromophenyl)fluorene, 9,9-bis(4-hydroxy-3-fluorophenyl)fluorene, 9,9-bis(4-hydroxy-3-methoxyphenyl)fluorene, 9,9-bis(4-hydroxy-3,5-dimethylphenyl)fluorene, 9,9-bis(4-hydroxy-3,5-dichlorophenyl)fluorene, 9,9-bis(4-hydroxy-3,5-dibromophenyl)fluorene, or a combination of the compounds.

Specific examples of epihalohydrin include epichlorohydrin, epibromohydrin, or a combination of the compounds.

Specific examples of the bisphenol fluorene-type compound having an epoxy group include (1) a product made by Nippon Steel Chemical such as ESF-300 or a similar compound thereof; (2) a product made by Osaka Gas such as PG-100, EG-210, or a similar compound thereof; and (3) a product made by S.M.S. Technology Co. such as SMS-F9PhPG, SMS-F9CrG, SMS-F914PG, or a similar compound thereof.

The compound (a-1-ii) having at least one carboxylic acid group and at least one ethylenically unsaturated group is at least one compound selected from the group consisting of, for instance, the following compounds: acrylic acid, methacrylic acid, 2-methacryloyloxyethylbutanedioic acid, 2-methacryloyloxybutylbutanedioic acid, 2-methacryloyloxyethylhexanedioic acid, 2-methacryloyloxybutylhexanedioic acid, 2-methacryloyloxyethylhexahydrophthalic acid, 2-methacryloyloxyethylmaleic acid, 2-methacryloyloxypropylmaleic acid, 2-methacryloyloxybutylmaleic acid, 2-methacryloyloxypropylbutanedioic acid, 2-methacryloyloxypropylhexanedioic acid, 2-methacryloyloxypropyltetrahydrophthalic acid, 2-methacryloyloxypropylphthalic acid, 2-methacryloyloxybutylphthalic acid, or 2-methacryloyloxybutylhydrophthalic acid; a compound obtained by reacting (meth)acrylate containing a hydroxyl group and a dicarboxylic acid compound, wherein the dicarboxylic acid compound contains, but is not limited to, adipic acid, succinic acid, maleic acid, or phthalic acid; and a hemiester compound obtained by reacting (meth)acrylate containing a hydroxyl group and a carboxylic acid anhydride compound, wherein the (meth)acrylate containing a hydroxyl group contains, but is not limited to, (2-hydroxyethyl) acrylate, (2-hydroxyethyl) methacrylate, (2-hydroxypropyl) acrylate, (2-hydroxypropyl) methacrylate, (4-hydroxybutyl) acrylate, (4-hydroxybutyl) methacrylate, or pentaerythritol trimethacrylate. Moreover, specific examples of the carboxylic acid anhydride compound can be the same as the specific examples of the tetracarboxylic acid dianhydride in the other tetracarboxylic acids or an acid dianhydride thereof (a-2-2) below and the specific examples of the dicarboxylic acid anhydride in the other dicarboxylic acids or an acid anhydride thereof (a-3-2) below, and are therefore not repeated herein.

Tetracarboxylic Acid or Acid Dianhydride Thereof (a-2)

The tetracarboxylic acid or an acid dianhydride thereof (a-2) includes a tetracarboxylic acid or an acid dianhydride thereof (a-2-1) containing a fluorine atom, other tetracarboxylic acids or an acid dianhydride thereof (a-2-2) other than the tetracarboxylic acid or an acid dianhydride thereof (a-2-1) containing a fluorine atom, or a combination of the two.

The tetracarboxylic acid or an acid dianhydride thereof (a-2-1) containing a fluorine atom is selected from the group consisting of a tetracarboxylic acid compound containing a fluorine atom represented by formula (2-1) and a tetracarboxylic acid dianhydride compound containing a fluorine atom represented by formula (2-2). Specifically, the tetracarboxylic acid compound containing a fluorine atom represented by formula (2-1) and the tetracarboxylic acid dianhydride compound containing a fluorine atom represented by formula (2-2) are as shown below.

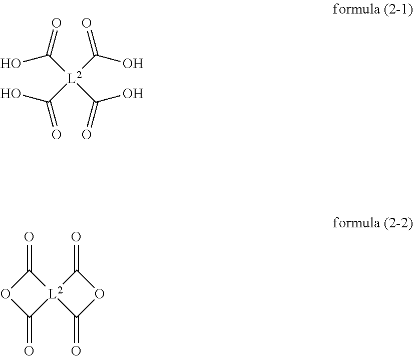

In formula (2-1) and formula (2-2), L² is a tetravalent aromatic group having fluorine and preferably has a benzene ring. Specifically, one of the groups represented by formula (L-1) to (L-6) is preferred.

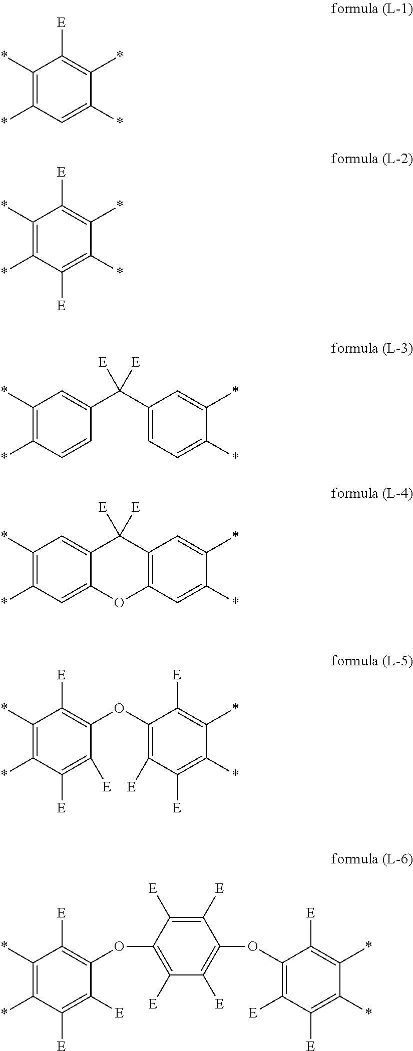

In formula (L-1) to formula (L-6), E each independently represents a fluorine atom or a trifluoromethyl group, and * represents the location of bonding with a carbon atom.

In detail, specific examples of the tetracarboxylic acid or an acid dianhydride thereof (a-2-1) containing a fluorine atom include an aromatic tetracarboxylic acid containing fluorine such as 4,4′-hexafluoro isopropylidene diphthalic acid, 1,4-difluoropyromellitic acid, 1-monofluoropyromellitic acid, or 1,4-ditrifluoromethylpyromellitic acid, a dianhydride compound of the tetracarboxylic acids, or a combination of the compounds.

Specific examples of the tetracarboxylic acid containing a fluorine atom or an acid dianhydride thereof (a-2-1) further include a tetracarboxylic acid containing fluorine such as 3,3′-(hexafluoro isopropylidene) diphthalic acid, 5,5′-[2,2,2-trifluoro-1-[3-(trifluoromethyl) phenyl]ethylidene]diphthalic acid, 5,5′-[2,2,3,3,3-pentafluoro-1-(trifluoromethyl) propylidene]diphthalic acid, 5,5′-oxybis[4,6,7-trifluoro-pyromellitic acid], 3,6-bis(trifluoromethyl)pyromellitic acid, 4-(trifluoromethyl) pyromellitic acid, or 1,4-bis(3,4-dicarboxylic acid trifluorophenoxy)tetrafluoro benzene, a dianhydride compound of the tetracarboxylic acids, or a combination of the compounds.

The other tetracarboxylic acids or an acid dianhydride thereof (a-2-2) include a saturated straight-chain hydrocarbon tetracarboxylic acid, an alicyclic tetracarboxylic acid, an aromatic tetracarboxylic acid, a dianhydride compound of the tetracarboxylic acids, or a combination thereof.

Specific examples of the saturated straight-chain hydrocarbon tetracarboxylic acid include butanetetracarboxylic acid, pentanetetracarboxylic acid, hexanetetracarboxylic acid, or a combination of the compounds. The saturated straight-chain hydrocarbon tetracarboxylic acid can also have a substituent.

Specific examples of the alicyclic tetracarboxylic acid include cyclobutanetetracarboxylic acid, cyclopentanetetracarboxylic acid, cyclohexanetetracarboxylic acid, norbornane tetracarboxylic acid, or a combination of the compounds. The alicyclic tetracarboxylic acid can also have a substituent.

Specific examples of the aromatic tetracarboxylic acid include pyromellitic acid, benzophenone tetracarboxylic acid, biphenyltetracarboxylic acid, biphenylether tetracarboxylic acid, diphenylsulfonetetracarboxylic acid, 1,2,3,6-tetrahydrophthalic acid, or a combination of the compounds. The aromatic tetracarboxylic acid can also have a substituent.

Dicarboxylic Acid or an Acid Anhydride Thereof (a-3)

The dicarboxylic acid or an acid anhydride thereof (a-3) includes a dicarboxylic acid or an acid anhydride thereof (a-3-1) containing a fluorine atom, other dicarboxylic acids or an acid anhydride thereof (a-3-2) other than the dicarboxylic acid or an acid anhydride thereof (a-3-1) containing a fluorine atom, or a combination of the two.

The dicarboxylic acid or an acid anhydride thereof (a-3-1) containing a fluorine atom is selected from the group consisting of a dicarboxylic acid compound containing a fluorine atom represented by formula (3-1) and a dicarboxylic acid anhydride compound containing a fluorine atom represented by formula (3-2). Specifically, the dicarboxylic acid compound containing a fluorine atom represented by formula (3-1) and the dicarboxylic acid anhydride compound containing a fluorine atom represented by formula (3-2) are as shown below.

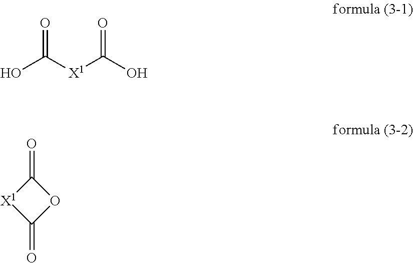

In formula (3-1) and formula (3-2), X¹ represents a C₁ to C₁₀₀ organic group containing a fluorine atom.

Specific examples of the dicarboxylic acid or an acid anhydride thereof (a-3-1) containing a fluorine atom include 3-fluorophthalic acid, 4-fluorophthalic acid, tetrafluorophthalic acid, 3,6-difluorophthalic acid, tetrafluoro succinic acid, an acid anhydride compound of the dicarboxylic acids, or a combination of the compounds.

Specific examples of the other dicarboxylic acids or an acid anhydride thereof (a-3-2) include a saturated straight-chain hydrocarbon dicarboxylic acid, a saturated cyclic hydrocarbon dicarboxylic acid, an unsaturated dicarboxylic acid, an acid anhydride of the dicarboxylic acid compounds, or a combination of the compounds.

Specific examples of the saturated straight-chain hydrocarbon dicarboxylic acid include succinic acid, acetyl succinic acid, adipic acid, azelaic acid, citramalic acid, malonic acid, glutaric acid, citric acid, tataric acid, ketogluconic acid, pimelic acid, sebacic acid, suberic acid, diglycolic acid, or a combination of the compounds. The hydrocarbon group in the saturated straight-chain hydrocarbon dicarboxylic acid can also be substituted.

Specific examples of the saturated cyclic hydrocarbon dicarboxylic acid include hexahydrophthalic acid, cyclobutanedicarboxylic acid, cyclopentanedicarboxylic acid, norbornanedicarboxylic acid, hexahydrotrimellitic acid, or a combination of the compounds. The saturated cyclic hydrocarbon dicarboxylic acid can also be an alicyclic dicarboxylic acid in which a saturated hydrocarbon is substituted.

Specific examples of the unsaturated dicarboxylic acid include maleic acid, itaconic acid, phthalic acid, tetrahydrophthalic acid, methyl endo-methylene tetrahydro phthalic acid, chlorendic acid, trimellitic acid, or a combination of the compounds.

Specific examples of the other dicarboxylic acids or an acid anhydride thereof (a-3-2) include a dicarboxylic acid anhydride such as trimethoxysilylpropyl succinic anhydride, triethoxysilylpropyl succinic anhydride, methyldimethoxysilylpropyl succinic anhydride, methyldiethoxysilylpropyl succinic anhydride, trimethoxysilylbutyl succinic anhydride, triethoxysilylbutyl succinic anhydride, methyldiethoxysilylbutyl succinic anhydride, para-(trimethoxysilyl)phenyl succinic anhydride, para-(triethoxysilyl)phenyl succinic anhydride, para-(methyldimethoxysilyl)phenyl succinic anhydride, para-(methyldiethoxysilyl)phenyl succinic anhydride, meta-(trimethoxysilyl)phenyl succinic anhydride, meta-(triethoxysilyl)phenyl succinic anhydride, or meta-(methyldiethoxysilyl)phenyl succinic anhydride, a dicarboxylic acid compound of the dicarboxylic acid anhydrides, or a combination of the compounds.

The dicarboxylic acid compound is preferably succinic acid, itaconic acid, tetrahydrophthalic acid, hexahydrotrimellitic acid, phthalic acid, trimellitic acid, or a combination of the compounds, and is more preferably succinic acid, itaconic acid, tetrahydrophthalic acid, or a combination of the compounds.

The dicarboxylic acid anhydride is preferably butanedioic anhydride, itaconic anhydride, tetrahydrophthalic anhydride, hexahydrotrimellitic anhydride, phthalic anhydride, trimellitic anhydride, or a combination of the compounds.

The method for synthesizing the alkali-soluble resin (A-1) is not particularly limited, and the alkali-soluble resin (A-1) can be obtained as long as the diol compound (a-1) containing a polymeric unsaturated group, the tetracarboxylic acid dianhydride or a tetracarboxylic acid thereof (a-2), and the dicarboxylic acid anhydride or a dicarboxylic acid thereof (a-3) are reacted.

When preparing the alkali-soluble resin (A-1), to speed up the reaction, an alkali compound is generally added in the reaction solution as a reaction catalyst. Specific examples of the reaction catalyst include, for instance, triphenyl phosphine, triphenyl stibine, triethylamine, triethanolamine, tetramethylammonium chloride, benzyltriethylammonium chloride, or a combination of the reaction catalysts. The reaction catalyst can be used alone or in multiple combinations.

Moreover, to control the degree of polymerization, an inhibitor is generally added in the reaction solution. Specific examples of the inhibitor include methoxyphenol, methylhydroquinone, hydroquinone, 2,6-di-tert-butyl-p-cresol, phenothiazine, or a similar compound thereof. The inhibitor can be used alone or in multiple combinations.

When preparing the alkali-soluble resin (A-1), a polymerization solvent can be used when needed. Specific examples of the polymerization solvent include: an alcohol compound such as ethanol, propanol, isopropanol, butanol, isobutanol, 2-butanol, hexanol, ethylene glycol, or a similar compound thereof; a ketone compound such as methyl ethyl ketone, cyclohexanone, or a similar compound thereof; an aromatic hydrocarbon compound such as toluene, xylene, or a similar compound thereof; a cellosolve compound such as cellosolve, butyl cellosolve, or a similar compound thereof; a carbitol compound such as carbitol, butyl carbitol, or a similar compound thereof; a propylene glycol alkyl ether compound such as propylene glycol monomethyl ether or a similar compound thereof; a poly(propylene glycol) alkyl ether compound such as di(propylene glycol) methyl ether or a similar compound thereof; an acetate compound such as ethyl acetate, butyl acetate, ethylene glycol monoethyl ether acetate, propylene glycol methyl ether acetate, propylene glycol monomethyl ether acetate, or a similar compound thereof; an alkyl lactate compound such as ethyl lactate, butyl lactate, or a similar compound thereof; a dialkyl glycol ether; or other esters such as methyl 2-hydroxy-2-methylpropionate, ethyl 2-hydroxy-2-methylpropionate, methyl 3-methoxypropionate, ethyl 3-methoxypropionate, methyl 3-ethoxypropionate, ethyl 3-ethoxypropionate (EEP), or ethyl ethoxyacetate. The polymerization solvent can be used alone or in multiple combinations. Moreover, the acid value of the alkali-soluble resin (A-1) is 50 mgKOH/g to 200 mgKOH/g, preferably 60 mgKOH/g to 180 mgKOH/g.

Moreover, the synthesis method can include a known method for reacting a diol compound and tetracarboxylic acid dianhydride at a reaction temperature of 90° C. to 140° C. as described in Japanese Laid-Open Patent Publication No. 9-325494. Moreover, the first mixture is uniformly dissolved and reacted at a reaction temperature of 90° C. to 130° C. and then reacted and aged at a reaction temperature of 40° C. to 80° C.

The alkali-soluble resin (A-1) obtained by reacting the first mixture is an alkali-soluble resin containing a fluorine atom, and is preferably an alkali-soluble resin containing an aromatic structure having fluorine.

Moreover, in each component of the first mixture forming the alkali-soluble resin (A-1), in the tetracarboxylic acid or an acid dianhydride thereof (a-2) and the dicarboxylic acid or an acid anhydride thereof (a-3), at least one of the two contains a fluorine atom, and preferably both the tetracarboxylic acid or an acid dianhydride thereof (a-2) and the dicarboxylic acid or an acid anhydride thereof (a-3) contain a fluorine atom. In the case that neither of the tetracarboxylic acid or an acid dianhydride thereof (a-2) and the dicarboxylic acid or an acid anhydride thereof (a-3) contains a fluorine atom, the resolution and the development resistance of the photosensitive resin composition are poor. Specifically, in the case that both the tetracarboxylic acid or an acid dianhydride thereof (a-2) and the dicarboxylic acid or an acid anhydride thereof (a-3) contain a fluorine atom, the tetracarboxylic acid or an acid dianhydride thereof (a-2) includes the tetracarboxylic acid or an acid dianhydride thereof (a-2-1) containing a fluorine atom, and the dicarboxylic acid or an acid anhydride thereof (a-3) includes the dicarboxylic acid or an acid anhydride thereof (a-3-1) containing a fluorine atom.

Based on a usage amount of 100 parts by weight of the alkali-soluble resin (A), the usage amount of the first alkali-soluble resin (A-1) can be 10 parts by weight to 100 parts by weight, preferably 12 parts by weight to 100 parts by weight, and more preferably 15 parts by weight to 100 parts by weight.

It should be mentioned that, in the case that the alkali-soluble resin (A) does not contain the first alkali-soluble resin (A-1), the adhesion of the photosensitive resin composition is poor. More specifically, in the case that the photosensitive resin composition contains the first alkali-soluble resin (A-1), since the fluorine atom can effectively increase water repellency of the alkali-soluble resin, in the subsequent development step, the exposed portion does not readily fall off due to lateral etching. As a result, the issue of poor adhesion of the photosensitive resin composition can be solved.

Moreover, the number of moles of the diol compound (a-1) containing a polymeric unsaturated group, the number of moles of the tetracarboxylic acid or an acid dianhydride thereof (a-2-1) containing a fluorine atom, and the number of moles of the dicarboxylic acid or an acid anhydride thereof (a-3-1) containing a fluorine atom preferably can satisfy the relationship [(a-2-1)+(a-3-1)]/(a-1)=0.4-1.6. In the case that [(a-2-1)+(a-3-1)]/(a-1)=0.4-1.6, the adhesion of the photosensitive resin composition can be further increased.

### Second Alkali-Soluble Resin (A-2)

The second alkali-soluble resin (A-2) includes a derived unit having a structure represented by formula (4).

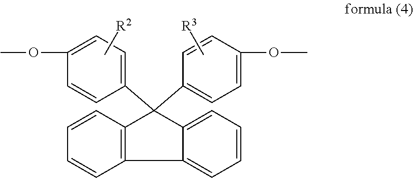

In formula (4), R² and R³ are each independently a hydrogen atom, a C₁ to C₅ straight-chain or branch-chain alkyl group, a phenyl group, or a halogen atom.

The second alkali-soluble resin (A-2) is obtained by reacting a compound having a structure represented by formula (4) and other copolymerizable compounds. The compound having a structure represented by formula (4) can be a bisphenol fluorene-type compound containing two epoxy groups represented by formula (5) or a bisphenol fluorene-type compound containing two hydroxyl groups represented by formula (6).

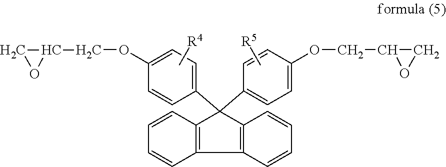

In formula (5), R⁴ is the same as R² of formula (4); R⁵ is the same as R³ of formula (4), and R⁴ and R⁵ are not repeated herein.

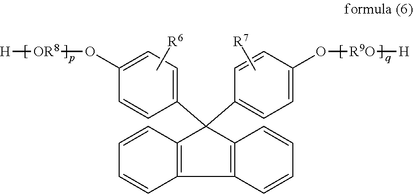

In formula (6), R⁶ is the same as R² of formula (4); R⁷ is the same as R³ of formula (4), and R⁶ and R⁷ are not repeated herein; R⁸ and R⁹ each independently represent a C₁ to C₂₀ alkylene group or alicyclic group; and p and q each independently represent an integer of 1 to 4.

Specific examples of the other copolymerizable compounds include an unsaturated monocarboxylic acid such as acrylic acid, methacrylic acid, butenoic acid, α-chloroacrylic acid, ethyl acrylic acid, or cinnamic acid; a dicarboxylic acid such as maleic acid, itaconic acid, succinic acid, phthalic acid, tetrahydrophthalic acid, hexahydrophthalic acid, methyl tetrahydrophthalic acid, methyl hexahydrophthalic acid, methyl endo-methylene tetrahydro phthalic acid, chlorendic acid, or glutaric acid, and an acid anhydride thereof; a tricarboxylic acid such as trimellitic acid and an acid anhydride thereof; and a tetracarboxylic acid such as pyromellitic acid, benzophenone tetracarboxylic acid, biphenyl tetracarboxylic acid, or biphenylether tetracarboxylic acid, an acid anhydride thereof, or a combination of the compounds.

The second alkali-soluble resin (A-2) is preferably a product made by Nippon Steel Chemical such as V259ME or V301ME.

Based on a usage amount of 100 parts by weight of the alkali-soluble resin (A), the usage amount of the second alkali-soluble resin (A-2) can be 0 parts by weight to 90 parts by weight, preferably 0 parts by weight to 88 parts by weight, and more preferably 0 parts by weight to 85 parts by weight.

### Other Alkali-Soluble Resins (A-3)

The alkali-soluble resin (A) can further optionally include other alkali-soluble resins (A-3). The other alkali-soluble resins (A-3) are resins other than the first alkali-soluble resin (A-1) and the second alkali-soluble resin (A-2). The other alkali-soluble resins (A-3) are, for instance, resins having a carboxylic acid group or a hydroxyl group, but are not limited to resins having a carboxylic acid group or a hydroxyl group. Specific examples of the other alkali-soluble resins (A-3) include a resin such as acrylic resin, urethane resin, or novolac resin.

The molecular weight of the other alkali-soluble resins (A-3) is preferably 3,000 to 100,000, more preferably 4,000 to 80,000, and still more preferably 5,000 to 60,000.

Based on a usage amount of 100 parts by weight of the alkali-soluble resin (A), the usage amount of the other alkali-soluble resins (A-3) is 0 parts by weight to 30 parts by weight, preferably 0 parts by weight to 20 parts by weight, and more preferably 0 parts by weight to 10 parts by weight.

### Compound (B) Having an Ethylenically Unsaturated Group

The compound (B) having an ethylenically unsaturated group can include a compound (B-1) having an acidic group and at least three ethylenically unsaturated groups. Moreover, the compound (B) having an ethylenically unsaturated group can also further include other compounds (B-2) having an ethylenically unsaturated group.

### Compound (B-1) Having an Acidic Group and at Least Three Ethylenically Unsaturated Groups

The acidic group in the compound (B-1) having an acidic group and at least three ethylenically unsaturated groups can generate an effect with an alkaline developing agent. Specific examples of the acidic group include, for instance, a carboxyl group, a sulfo group, or a phosphate group, wherein the acidic group is preferably a carboxyl group capable of generating a good effect with an alkaline developing agent.

The compound (B-1) having an acidic group and at least three ethylenically unsaturated groups includes (1) performing a modification reaction on a multi-functional (meth)acrylate having a hydroxyl group and a dicarboxylic acid anhydride or a dicarboxylic acid to synthesize a multi-functional (meth)acrylate containing a carboxyl group; and (2) performing a modification reaction on an aromatic multi-functional (meth)acrylate and concentrated sulfuric acid or oleum to synthesize a multi-functional (meth)acrylate containing a sulfo group.

The compound (B-1) having an acidic group and at least three ethylenically unsaturated groups preferably has a structure represented by formula (IV) or (V).

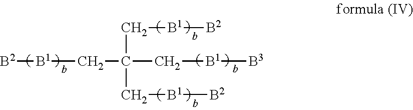

In formula (IV), B¹ represents —CH₂—, —OCH₂—, —OCH₂CH₂—, —OCH₂CH₂CH₂—, or —OCH₂CH₂CH₂CH₂—; B² represents a structure represented by formula (IV-1) or formula (IV-2); B³ represents a structure represented by formula (IV-3), formula (IV-4), or formula (IV-5), wherein a benzene ring in the structure represented by formula (IV-5) can also be tetrahydrogenated or hexahydrogenated, and c represents an integer of 1 to 8; and b represents an integer of 0 to 14. In the case of a plurality of B¹ and B², B¹ and B² can each be the same or different.

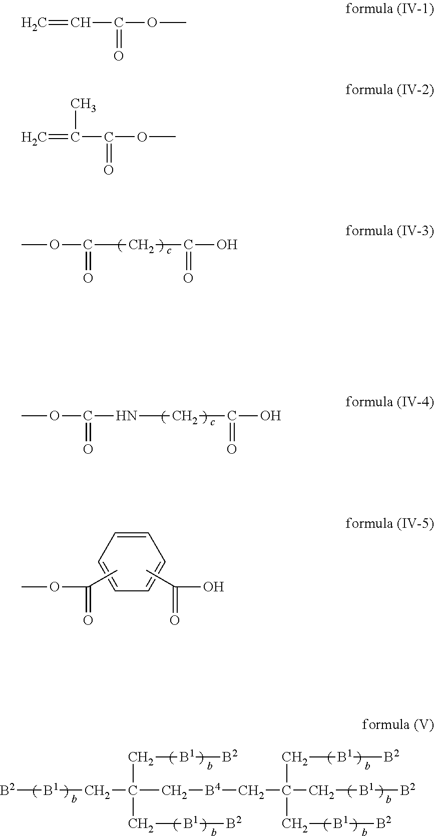

In formula (V), B¹, B², B³, and b are defined the same as B¹, B², B³, and b in formula (IV) and are not repeated herein; and B⁴ represents —O— or a structure represented by formula (V-1). In the case of a plurality of B¹ and B², B¹ and B² can each be the same or different.

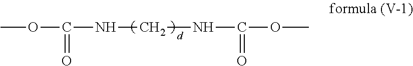

In formula (V-1), d represents an integer of 1 to 8.

The compound (B-1) having an acidic group and at least three ethylenically unsaturated groups represented by formula (IV) or formula (V) is, for instance, a compound having an acidic group and three ethylenically unsaturated groups or a compound having an acidic group and five ethylenically unsaturated groups.

Specific examples of the compound having an acidic group and three ethylenically unsaturated groups include monohydroxyl oligoacrylate or monohydroxyl oligomethacrylate such as pentaerythritol triacrylate, pentaerythritol trimethacrylate, dipentaerythritol pentaacrylate, or dipentaerythritol pentamethacrylate, and a monoester compound containing a carboxyl group formed by a diacid such as malonic acid, succinic acid, glutaric acid, isophthalic acid, terephthalic acid, or phthalic acid. Specific examples of commercial products of the compound having an acidic group and three ethylenically unsaturated groups include TO-756 (made by Toagosei Co., Ltd.), PE3A-MS, PE3A-MP (made by Kyoeisha Chemical Co., Ltd.), or a combination of the commercial products.

Specific examples of commercial products of the compound having an acidic group and five ethylenically unsaturated groups include TO-1382, TO-1385 (made by Toagosei Co., Ltd.), DPE6A-MS, DPE6A-MP (made by Kyoeisha Chemical Co., Ltd.), or a combination of the commercial products.

Specific examples of the compound (B-1) having an acidic group and at least three ethylenically unsaturated groups preferably include pentaerythritol triacrylate, pentaerythritol trimethacrylate, dipentaerythritol pentaacrylate, or dipentaerythritol pentamethacrylate, and a monoester compound containing a carboxyl group formed by succinic acid or phthalic acid.

The compound (B-1) having an acidic group and at least three ethylenically unsaturated groups can be used alone or in multiple combinations.

Based on a usage amount of 100 parts by weight of the alkali-soluble resin (A), the usage amount of the compound (B-1) having an acidic group and at least three ethylenically unsaturated groups can be 15 parts by weight to 150 parts by weight, preferably 20 parts by weight to 140 parts by weight, more preferably 25 parts by weight to 130 parts by weight.

It should be mentioned that, since the acidic group of the compound (B-1) having an acidic group and at least three ethylenically unsaturated groups can increase the van der Waals force between the black matrix formed by the photosensitive resin composition and a substrate (such as glass), and the at least three ethylenically unsaturated groups can participate in a photochemical reaction to increase the crosslink density of a cured product (black matrix), the adhesion and the hardness of the black matrix manufactured by the photosensitive resin composition can be increased.

### Other Compounds (B-2) Having an Ethylenically Unsaturated Group

The other compounds (B-2) having an ethylenically unsaturated group include a compound having one ethylenically unsaturated group, a compound having two or more ethylenically unsaturated groups, or a combination of the two.

Specific examples of the compound having one ethylenically unsaturated group include, bus are not limited to, for instance, (meth)acrylamide, (meth)acryloylmorpholine, 7-amino-3,7-dimethyloctyl(meth)acrylate, isobutoxymethyl(meth)acrylamide, isobornyloxyethyl(meth)acrylate, isobornyl(meth)acrylate, 2-ethylhexyl(meth)acrylate, ethyl diethylene glycol(meth)acrylate, t-octyl(meth)acrylamide, diacetone(meth)acrylamide, dimethylaminoethyl(meth)acrylate, dodecyl (meth)acrylate, dicyclopentenyloxyethyl(meth)acrylate, dicyclopentenyl(meth)acrylate, N,N-dimethyl(meth)acrylamide, tetrachlorophenyl(meth)acrylate, 2-tetrachlorophenoxy ethyl(meth)acrylate, tetrahydrofurfuryl(meth)acrylate, tetrabromophenyl(meth)acrylate, 2-tetrabromophenoxyethyl(meth)acrylate, 2-trichlorophenoxyethyl(meth)acrylate, tribromophenyl(meth)acrylate, 2-tribromophenoxyethyl(meth)acrylate, 2-hydroxyethyl(meth)acrylate, 2-hydroxypropyl(meth)acrylate, vinylcaprolactam, N-vinylpyrrolidone, phenoxyethyl(meth)acrylate, pentachlorophenyl(meth)acrylate, pentabromophenyl(meth)acrylate, polyethylene glycol mono(meth)acrylate, polypropylene glycol mono(meth)acrylate, bornyl (meth)acrylate, or a combination thereof. The compound having one ethylenically unsaturated group can be used alone or in multiple combinations.

Specific examples of the compound having two or more ethylenically unsaturated groups include, but are not limited to, ethylene glycol di(meth)acrylate, dicyclopentenyl di(meth)acrylate, triethylene glycol di(meth)acrylate, tetraethylene glycol di(meth)acrylate, tri(2-hydroxyethyl)isocyanate di(meth)acrylate, tri(2-hydroxyethyl)isocyanate tri(meth)acrylate, caprolactone-modified tri(2-hydroxyethyl)isocyanate tri(meth)acrylate, trimethylolpropyl tri(meth)acrylate, ethylene oxide (hereinafter EO)-modified trimethylolpropyl tri(meth)acrylate, propylene oxide (hereinafter PO)-modified trimethylolpropyl tri(meth)acrylate, tripropylene glycol di(meth)acrylate, neo-pentyl glycol di(meth)acrylate, 1,4-butanediol di(meth)acrylate, 1,6-hexanediol di(meth)acrylate, polyester di(meth)acrylate, polyethylene glycol di(meth)acrylate, dipentaerythritol hexa(meth)acrylate, dipentaerythritol penta(meth)acrylate, dipentaerythritol tetra(meth)acrylate, caprolactone-modified dipentaerythritol hexa(meth)acrylate, caprolactone-modified dipentaerythritol penta(meth)acrylate, di(trimethylolpropane) tetra(meth)acrylate, EO-modified bisphenol A di(meth)acrylate, PO-modified bisphenol A di(meth)acrylate, EO-modified hydrogenated bisphenol A di(meth)acrylate, PO-modified hydrogenated bisphenol A di(meth)acrylate, EO-modified bisphenol F di(meth)acrylate, novolac polyglycidyl ether (meth)acrylate, or a combination thereof. The compound having two or more ethylenically unsaturated groups can be used alone or in multiple combinations.

Specific examples of the other compounds (B-2) having an ethylenically unsaturated group preferably include trimethylolpropyl triacrylate, EO-modified trimethylolpropyl triacrylate, PO-modified trimethylolpropyl triacrylate, pentaerythritol triacrylate, pentaerythritol tetraacrylate, dipentaerythritol hexaacrylate, dipentaerythritol pentaacrylate, dipentaerythritol tetraacrylate, caprolactone-modified dipentaerythritol hexaacrylate, di(trimethylolpropyl) tetraacrylate, PO-modified glycerol triacrylate, or a combination thereof.

Based on a usage amount of 100 parts by weight of the alkali-soluble resin (A), the usage amount of the compound (B) having an ethylenically unsaturated group can be 15 parts by weight to 200 parts by weight, preferably 20 parts by weight to 190 parts by weight, more preferably 25 parts by weight to 180 parts by weight.

### Photoinitiator (C)

The photoinitiator (C) is, for instance, an acetophenone compound, a biimidazole compound, an acyl oxime compound, or a combination of the compounds.

Specific examples of the acetophenone-based compound include p-dimethylamino-acetophenone, α,α′-dimethoxyazoxy-acetophenone, 2,2′-dimethyl-2-phenyl-acetophenone, p-methoxy-acetophenone, 2-methyl-1-(4-methylthiophenyl)-2-morpholino-1-propanone, 2-benzyl-2-N,N-dimethylamino-1-(4-morpholinophenyl)-1-butanone, or a combination of the compounds.

Specific examples of the biimidazole-based compound include 2,2′-bis(o-chlorophenyl)-4,4′,5,5′-tetraphenyl-biimidazole, 2,2′-bis(o-fluorophenyl)-4,4′,5,5′-tetraphenyl-biimidazole, 2,2′-bis(o-methyl phenyl)-4,4′,5,5′-tetraphenyl-biimidazole, 2,2′-bis(o-methoxyphenyl)-4,4′,5,5′-tetraphenyl-biimidazole, 2,2′-bis(o-ethylphenyl)-4,4′,5,5′-tetraphenyl-biimidazole, 2,2′-bis(p-methoxyphenyl)-4,4′,5,5′-tetraphenyl-biimidazole, 2,2′-bis(2,2′,4,4′-tetramethoxyphenyl)-4,4′,5,5′-tetraphenyl-biimidazole, 2,2′-bis(2-chlorophenyl)-4,4′,5,5′-tetraphenyl-biimidazole, 2,2′-bis(2,4-dichlorophenyl)-4,4′,5,5′-tetraphenyl-biimidazole, or a combination of the compounds.

Specific examples of the acyl oxime compound include ethanone, 1-[9-ethyl-6-(2-methylbenzoyl)-9H-carbazole-3-yl]-,1-(O-acetyl oxime) such as OXE-02 made by Ciba Specialty Chemicals having a structure represented by formula (7), 1-(4-phenyl-thio-phenyl)-octane-1,2-dion 2-oxime-O-benzoate such as OXE-01 made by Ciba Specialty Chemicals having a structure represented by formula (8), ethanone, 1-[9-ethyl-6-(2-choler-4-benzyl-thio-benzoyl)-9H-carbazole-3-yl]-, 1-(0-acetyl oxime) made by Asahi Denka Co., Ltd. having a structure represented by formula (9), or a combination of the compounds.

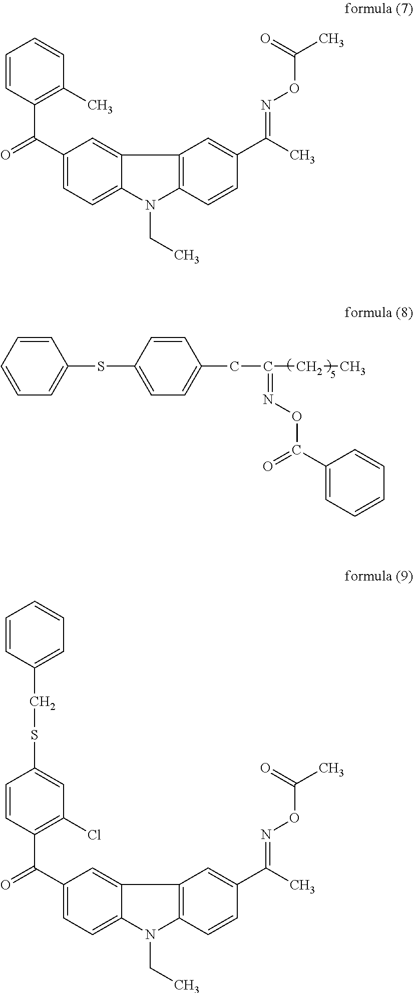 [SMILES: CCn1c2ccc(C(=O)c3ccccc3C)cc2c2cc(/C(C)=N/OC(C)=O)ccc21 ; CC/C(Cc1ccc(Sc2ccccc2)cc1)=N\OC(=O)c1ccccc1 ; CCn1c2ccc(C(=O)c3ccc(SCc4ccccc4)cc3Cl)cc2c2cc(/C(C)=N/OC(C)=O)ccc21]

The photoinitiator (C) is preferably 2-methyl-1-(4-methylthio phenyl)-2-morpholino-1-propanone, 2-benzyl-2-N,N-dimethylamino-1-(4-morpholinophenyl)-1-butanone, 2,2′-bis(o-chlorophenyl)-4,4′,5,5′-tetraphenyl-biimidazole, ethanone, 1-[9-ethyl-6-(2-methylbenzoyl)-9H-carbazole-3-yl]-, 1-(O-acetyl oxime), or a combination of the compounds.

The photoinitiator (C) can further include the following compounds as needed: a benzophenone compound such as thioxanthone, 2,4-diethyl-thioxanthanone, thioxanthone-4-sulfone, benzophenone, 4,4′-bis(dimethylamino)benzophenone, or 4,4′-bis(diethylamino)benzophenone; an α-diketone such as benzil or acetyl; an acyloin such as benzoin; an acyloin ether such as benzoin methylether, benzoin ethylether, or benzoin isopropyl ether; an acylphosphineoxide such as 2,4,6-trimethyl-benzoyl-diphenyl-phosphineoxide or bis-(2,6-dimethoxy-benzoyl)-2,4,4-trimethyl-benzyl-phosphineoxide; a quinone such as anthraquinone or 1,4-naphthoquinone; a halide such as phenacyl chloride, tribromomethyl-phenylsulfone, or tris(trichloromethyl)-s-triazine; a peroxide such as di-tertbutylperoxide, or a combination of the compounds. The compound added to the photoinitiator (C) is preferably a benzophenone compound, more preferably 4,4′-bis(diethylamino)benzophenone.

Based on a usage amount of 100 parts by weight of the alkali-soluble resin (A), the usage amount of the photoinitiator (C) can be 5 parts by weight to 55 parts by weight, preferably 7 parts by weight to 50 parts by weight, and more preferably 10 parts by weight to 45 parts by weight.

### Hyperbranched Polymer (D)

The hyperbranched polymer (D) can be a polymer formed by performing a Michael addition reaction on the multi-mercapto compound represented by formula (II) and the multi-functional (meth)acrylate represented by formula (I).

Specifically, the multi-functional (meth)acrylate represented by formula (I) is as shown below.

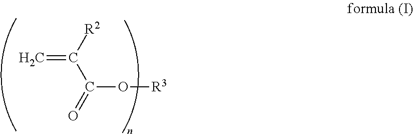

In formula (I), R² represents a hydrogen atom or a C₁ to C₄ alkyl group; R³ represents a residual group after the esterification of an n number of hydroxyl groups in a hydroxyl group-containing compound having an m number of hydroxyl groups, wherein m≧n, and n represents an integer of 2 to 20.

The hydroxyl group-containing compound is R⁴(OH)ₘ or a compound in which the R⁴(OH)ₘ is modified by propylene oxide, epichlorohydrin, an alkyl group, an alkoxy group, or hydroxypropyl acrylate.

The R⁴(OH)ₘ is a C₂ to C₁₈ polyalcohol, polyhydric alcohol ether formed by the polyalcohol, an ester formed by reacting the polyalcohol and an acid, or silicone.

Moreover, the multi-mercapto compound represented by formula (II) is as shown below.

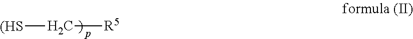

In formula (II), R⁵ represents a single bond, a C₁ hydrocarbon group, or a C₂ to C₂₂ straight-chain or branched-chain hydrocarbon group, the skeleton of R⁵ may further include a sulfur atom or an oxygen atom formed in an ester group (i.e., R⁵ is a single bond, a C₁ hydrocarbon group, a C₂ to C₂₂ straight-chain or branched-chain hydrocarbon group containing a sulfur atom or an oxygen atom, or a C₂ to C₂₂ straight-chain or branched-chain hydrocarbon group without a sulfur atom or an oxygen atom); p represents an integer of 2 to 6, wherein in the case that R⁵ represents a single bond, p represents 2; in the case that R⁵ represents a C₁ hydrocarbon group, p represents an integer of 2 to 4; and in the case that R⁵ represents a C₂ to C₂₂ straight-chain or branched-chain hydrocarbon group, p represents an integer of 2 to 6.

Moreover, the hyperbranched polymer (D) of the invention is preferably a polymer formed by reacting a remaining (meth)acrylate group from a reaction of the multi-mercapto compound represented by formula (II) and the multi-functional (meth)acrylate represented by formula (I) with a mercapto compound having a carboxyl group represented by formula (III).

The mercapto compound having a carboxyl group represented by formula (III) is as shown below.

HS—R⁶COOH)_{q} formula (III)

In formula (III), R⁶ represents a C₁ to C₁₂ alkylene group and q represents an integer of 1 to 3.

Specifically, a mercapto group contained in the multi-mercapto compound represented by formula (II) and the mercapto compound having a carboxyl group represented by formula (III) are added to a carbon-carbon double bond of the multi-functional (meth)acrylate represented by formula (I) via a photoreaction. In general, in the carbon-carbon double bond of the multi-functional (meth)acrylate represented by formula (I), the carbon-carbon double bond in the photoreaction is preferably 0.1% to 50% with respect to all of the carbon-carbon double bonds.

More specifically, the addition molar ratio of a mercapto group of the multi-mercapto compound represented by formula (II) or a mercapto group of the multi-mercapto compound represented by formula (II) and the mercapto compound having a carboxyl group represented by formula (III) with respect to the carbon-carbon double bond of the multi-functional (meth)acrylate represented by formula (I) can be 1/200 to 1/2, preferably 1/100 to 1/3, more preferably 1/50 to 1/5, and still more preferably 1/20 to 1/8.

The hyperbranched polymer (D) preferably has a sufficient number of a photopolymerizable functional group such as a carbon-carbon double bond. Specifically, the molecular weight of the hyperbranched polymer (D) corresponding to every 1 mole of the carbon-carbon double bond is preferably 100 to 100,000. The molecular weight of the hyperbranched polymer (D) is preferably 1,000 to 50,000, more preferably 1,500 to 40,000, and still more preferably 2,000 to 30,000.

Moreover, to manufacture a photosensitive resin composition capable of alkali development, the hyperbranched polymer (D) preferably has a sufficient number of a carboxyl group. Specifically, the molecular weight of the hyperbranched polymer (D) corresponding to every 1 mole of the carboxyl group is preferably 200 to 20,000, more preferably 250 to 6,000.

The number (n) of the acrylate group contained in the multi-functional (meth)acrylate represented by formula (I) is preferably 2 to 20, more preferably 2 to 10, and still more preferably 2 to 6. In the case that R² in formula (I) represents a C₁ to C₄ alkyl group, R² can be methyl, ethyl, propyl, or butyl, preferably methyl. Moreover, the number of carbons in R⁴(OH)ₘ is preferably 2 to 18, more preferably 2 to 14, and still more preferably 4 to 12.

Specific examples of the multi-functional (meth)acrylate represented by formula (I) include (meth)acrylate such as ethylene glycol di(meth)acrylate, diethylene glycol di(meth)acrylate, triethylene glycol di(meth)acrylate, tetraethylene glycol di(meth)acrylate, tetramethylene glycol di(meth) acrylate, trimethylol propane tri(meth)acrylate, EO-modified trimethylol propane tri(meth)acrylate, PO-modified trimethylol propane tri(meth)acrylate, trimethylol ethane tri(meth)acrylate, pentaerythritol di(meth)acrylate, pentaerythritol tri(meth)acrylate, pentaerythritol tetra(meth)acrylate, dipentaerythritol penta(meth)acrylate, dipentaerythritol hexa(meth)acrylate, tripentaerythritol octa(meth)acrylate, tripentaerythritol hepta(meth)acrylate, caprolactone-modified pentaerythritol tri(meth)acrylate, caprolactone-modified pentaerythritol tetra(meth)acrylate, caprolactone-modified dipentaerythritol hexa(meth)acrylate, epichlorohydrin-modified hexahydrophthalic acid di(meth)acrylate, hydroxypivalic acid neopentyl glycol di(meth)acrylate, neopentyl glycol di(meth)acrylate, EO-modified neopentyl glycol di(meth)acrylate, PO-modified neopentyl glycol di(meth)acrylate, caprolactone-modified hydroxypivalic acid neopentyl glycol di(meth)acrylate, stearic acid-modified pentaerythritol di(meth)acrylate, epichlorohydrin-modified phthalic acid di(meth)acrylate, poly(ethylene glycol tetramethylene glycol) di(meth)acrylate, poly(propylene glycol tetramethylene glycol) di(meth)acrylate, polyester (meth)acrylate, polyethylene glycol di(meth)acrylate, polyethylene glycol polypropylene glycol polyethylene glycol di(meth)acrylate, polypropylene glycol di(meth)acrylate, epichlorohydrin-modified propylene glycol di(meth)acrylate, PO-modified bisphenol A diglycidyl ether di(meth)acrylate, silicone di(meth)acrylate, tricyclodecane dimethanol di(meth)acrylate, neopentyl glycol-modified trimethylol propane di(meth)acrylate, tripropylene glycol di(meth)acrylate, EO-modified tripropylene glycol di(meth)acrylate, triglycerol di(meth)acrylate, dipropylene glycol di(meth)acrylate, epichlorohydrin-modified glycerol tri(meth)acrylate, EO-modified glycerol tri(meth)acrylate, PO-modified glycerol tri(meth)acrylate, EO-modified phosphoric acid tri(meth)acrylate, caprolactone-modified trimethylol propane tri(meth)acrylate, hydroxypropyl acrylate (HPA)-modified trimethylol propane tri(meth)acrylate, EO-modified trimethylol propane tri(meth)acrylate, PO-modified trimethylol propane tri(meth)acrylate, trimethylolpropane benzoate (meth)acrylate, tri((meth)acryloylethyl)isocyanurate, alkoxy-modified trimethylol propane tri(meth)acrylate, dipentaerythritol poly(meth)acrylate, alkyl-modified dipentaerythritol tri(meth)acrylate, ditrimethylolpropane tetra(meth)acrylate, or a combination of the compounds.

The number of carbons of R⁵ in the multi-mercapto compound represented by formula (II) is preferably 0 to 22 (in the case that the number of carbons is 0, R⁴ is a single bond, and formula (II) represents HS—CH₂—CH₂—SH), more preferably 1 to 16, and still more preferably 2 to 12. Specific examples of the multi-mercapto compound represented by formula (II) include 1,2-dimercaptoethane, 1,3-dimercaptopropane, 1,4-dimercaptobutane, bisdimercaptoethanethiol (HS—CH₂CH₂—S—CH₂CH₂—SH), dimercapto triethylene glycol, trimethylolpropane tri(mercaptoacetate), trimethylolpropane tri(mercaptopropionate), pentaerythritol tetra(mercaptoacetate), pentaerythritol tri(mercaptoacetate), pentaerythritol tetra(mercaptopropionate), dipentaerythritol hexa(mercaptoacetate), dipentaerythritol hexa(mercaptopropionate), or a combination of the compounds.

The alkylene group having a number of carbons of 1 to 12 of R⁶ in the mercapto compound having a carboxyl group represented by formula (III) can be a straight-chain or branched-chain alkylene group. Specifically, the alkylene group is, for instance, a group such as a methylene group, an ethylene group, a propylene group, a butylene group, an amylene group, a hexylene group, a heptylene group, an octylene group, a nonylene group, a decylene group, an undecylene group, or a dodecylene group. The mercapto compound having a carboxyl group represented by formula (III) can include, for instance, thioglycolic acid.

In the invention, the addition reaction can be performed by first mixing the multi-functional (meth)acrylate (monomer) represented by formula (I) and the multi-mercapto compound represented by formula (II) at room temperature to 100° C. and adding a basic catalyst. The reaction time is generally 30 minutes to about 6 hours. As a result, a hyperbranched polymer can be obtained.

Next, the mercapto compound having a carboxyl group represented by formula (III) can also be added to the hyperbranched polymer, and then another addition reaction is performed. As a result, a hyperbranched polymer having a carboxyl group can be obtained.

Moreover, a general analytical instrument of, for instance, liquid chromatography or gel filtration chromatography can be used to confirm the end of the synthesis of the hyperbranched polymer (D).

Moreover, when the hyperbranched polymer (D) is synthesized, an inhibitor can be added according to need. The inhibitor can include a general hydroquinone compound, phenolic compound, or a combination thereof used to suppress the polymerization of a (meth)acrylate compound. Specific examples of the inhibitor include, but are not limited to, hydroquinone, methoxyhydroquinone, catechol, p-tert-butylcatechol, cresol, butylated hydroxytoluene, 2,4,6-tris-tert-butyl phenol (BHT), or a combination of the compounds.

Based on a usage amount of 100 parts by weight of the alkali-soluble resin (A), the usage amount of the hyperbranched polymer (D) can be 3 parts by weight to 35 parts by weight, preferably 4 parts by weight to 30 parts by weight, and more preferably 5 parts by weight to 25 parts by weight.

It should be mentioned that, in the case that the photosensitive resin composition does not contain the hyperbranched polymer (D), the adhesion and the hardness of the photosensitive resin composition are poor. Specifically, in the case that the photosensitive resin composition contains the hyperbranched polymer (D), a mercapto group of the hyperbranched polymer (D) can increase the affinity between the black matrix formed by the photosensitive resin composition and a substrate (such as glass). As a result, the issue of poor adhesion of the black matrix manufactured by the photosensitive resin composition can be solved. Moreover, the hyperbranched polymer further has an ethylenically unsaturated group, thus increasing the crosslink density of a cured product. As a result, the issue of poor hardness of the black matrix can be solved.

Moreover, in the case that the hyperbranched polymer (D) has a carboxyl group, the van der Waals force between the black matrix formed by the photosensitive resin composition and a substrate (such as glass) can be increased, and the carboxyl group can participate in a photochemical reaction to increase the crosslink density of a cured product (black matrix). As a result, the adhesion and the hardness of the black matrix manufactured by the photosensitive resin composition can be further increased.

### Solvent (E)

The solvent (E) refers to an organic solvent capable of dissolving the alkali-soluble resin (A), the compound (B) having an ethylenically unsaturated group, the photoinitiator (C), the hyperbranched polymer (D), and the black pigment (F) but does not react with the components, and preferably has a suitable volatility.

The solvent (E) is, for instance, a (poly)alkylene glycol monoalkyl ether, a (poly)alkylene glycol monoalkyl ether acetate, other ethers, a ketone, an alkyl lactate, other esters, an aromatic hydrocarbon compound, a carboxylic acid amide, or a combination of the solvents.

Specific examples of the (poly)alkylene glycol monoalkyl ether include ethylene glycol monomethyl ether, ethylene glycol monoethyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, tripropylene glycol monoethyl ether, or a combination of the solvents.

Specific examples of the (poly)alkylene glycol monoalkyl ether acetate include ethylene glycol monomethyl ether acetate, ethylene glycol monoethyl ether acetate, propylene glycol monomethyl ether acetate, propylene glycol monoethyl ether acetate, or a combination of the solvents.

Specific examples of the other ethers include diethylene glycol dimethyl ether, diethylene glycol methyl ethyl ether, diethylene glycol diethyl ether, tetrahydrofuran, or a combination of the solvents.

Specific examples of the ketone include methyl ethyl ketone, cyclohexanone, 2-heptanone, 3-heptanone, or a combination of the solvents.

Specific examples of the alkyl lactate include methyl 2-hydroxypropionate, ethyl 2-hydroxypropionate, or a combination of the solvents.

Specific examples of the other esters include methyl 2-hydroxy-2-methylpropionate, ethyl 2-hydroxy-2-methylpropionate, methyl 3-methoxypropionate, ethyl 3-methoxypropionate, methyl 3-ethoxypropionate, ethyl 3-ethoxypropionate (EEP), ethyl ethoxyacetate, ethyl hydroxyacetate, methyl 2-hydroxy-3-methylbutyrate, 3-methyl-3-methoxybutyl acetate, 3-methyl-3-methoxybutylpropionate, ethyl acetate, n-propyl acetate, isopropylacetate, n-butyl acetate, isobutyl acetate, n-pentyl acetate, isopentyl acetate, n-butyl propionate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, ethyl 2-oxybutyrate, or a combination of the solvents.

Specific examples of the aromatic hydrocarbon compound include toluene, xylene, or a combination of the solvents.

Specific examples of the carboxylic acid amide include N-methylpyrrolidone, N,N-dimethyl formamide, N,N-dimethyl acetamide, or a combination of the solvents.

The solvent (E) is preferably propylene glycol monomethyl ether acetate, EEP, or a combination of the solvents. The solvent (E) can be used alone or in multiple combinations.

Based on a usage amount of 100 parts by weight of the alkali-soluble resin (A), the usage amount of the solvent (E) can be 1000 parts by weight to 5000 parts by weight, preferably 1200 parts by weight to 4500 parts by weight, and more preferably 1400 parts by weight to 4000 parts by weight.

### Black Pigment (F)

The black pigment (F) is preferably a black pigment having heat resistance, light resistance, and solvent resistance.

Specific examples of the black pigment (F) include: a black organic pigment such as perylene black, cyanine black, or aniline black; a near-black mixture of organic pigments obtained by mixing two or more pigments selected from the pigments of, for instance, red, blue, green, purple, yellow, cyanine, or magenta; a light-shielding material such as carbon black, chromium oxide, ferric oxide, titanium black, or graphite, wherein specific examples of the carbon black include C.I. pigment black 1 or 7 or a commercial product made by Mitsubishi Chemical (product name MA100, MA230, MA8, #970, #1000, #2350, or #2650). The black pigment (F) can be used alone or in multiple combinations.

The black pigment (F) is preferably carbon black or C.I. pigment black 7, and the carbon black is, for instance, the commercial product MA100 or MA230 made by Mitsubishi Chemical Corporation.

Based on a usage amount of 100 parts by weight of the alkali-soluble resin (A), the usage amount of the black pigment (F) can be 60 parts by weight to 600 parts by weight, preferably 80 parts by weight to 500 parts by weight, and more preferably 100 parts by weight to 400 parts by weight.

### Additive (G)

Under the premise of not affecting the efficacy of the invention, the photosensitive resin composition of the invention can optionally further include an additive (G). Specific examples of the additive (G) include a surfactant, a filler, a polymer (other than the alkali-soluble resin (A)), an adhesion promoter, an antioxidant, an ultraviolet absorber, or an anti-coagulant.

The surfactant helps to improve the coating properties of the photosensitive resin composition. Specific examples of the surfactant include a cationic surfactant, an anionic surfactant, a nonionic surfactant, an amphoteric surfactant, a polysiloxane surfactant, a fluorine surfactant, or a combination of the surfactants.

Specifically, the surfactant is, for instance, a polyoxyethylene alkyl ether such as polyoxyethylene lauryl ether, polyoxyethylene stearyl amine ether, or polyoxyethylene oleyl ether; a polyoxyethylene alkyl phenyl ether such as polyoxyethylene octyl phenyl ether or polyoxyethylene nonyl phenyl ether; a polyethylene glycol diester such as polyethylene glycol dilaurate or polyethylene glycol stearyl ether; a sorbitan fatty acid ester; a fatty acid-modified polyester; or tertiary amine-modified polyurethane. The surfactant can be used alone or in multiple combinations.

Specific examples of the surfactant include a KP product made by Shin-Etsu Chemical Co., Ltd., an SF-8427 product made by Dow Corning Toray Co., Ltd., a Polyflow product made by Kyoeisha Chemical Co. Ltd., an F-Top product made by Tochem Products Co., Ltd., a Megafac product made by DIC Corporation, a Fluorade product made by Sumitomo 3M Limited, an Asahi Guard product made by Asahi Glass Co., Ltd., or a Surflon product made by Asahi Glass Co., Ltd.

Specific examples of the filler include, for instance, glass or aluminum.

Specific examples of the polymer include polyvinyl alcohol, polyethylene glycol monoalkyl ether, polyfluoro alkyl acrylate, or a combination of the polymers.

Specific examples of the adhesion promoter include vinyltrimethoxysilane, vinyltriethoxysilane, vinyl-tris(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-glycidolpropyltrimethoxysilane, 3-glycidolpropylmethyldiethoxysilane, 3-glycidolpropylmethyldimethoxysilane, 2-(3,4-epoxycyclohexyl)ethyltrimethoxysilane, 3-chloropropylmethyldimethoxysilane, 3-chloropropyltrimethoxysilane, 3-methyl propionyloxy propyltrimethoxysilane, 3-mercaptopropyltrimethoxysilane, 3-glycidoxypropyltrimethoxysilane, or a combination of the compounds.

Specific examples of the antioxidant include 2,2-thiobis(4-methyl-6-tert-butylphenol), 2,6-di-tert-butylphenol, or a combination of the compounds.

Specific examples of the ultraviolet absorber include 2-(3-tert-butyl-5-methyl-2-hydroxyphenyl)-5-chlorophenylazide, alkoxy phenone, or a combination of the compounds.

Specific examples of the anti-coagulant include, for instance, sodium polyacrylate.

Based on a usage amount of 100 parts by weight of the alkali-soluble resin (A), the usage amount of the additive (G) is 0.1 part by weight to 10 parts by weight, preferably 0.5 parts by weight to 8 parts by weight, and more preferably 1 part by weight to 6 parts by weight.

### <Method for Preparing Photosensitive Resin Composition>

A method that can be used to prepare the photosensitive resin composition includes, for instance: placing and stirring the alkali-soluble resin (A), the compound (B) having an ethylenically unsaturated group, the photoinitiator (C), the hyperbranched polymer (D), the solvent (E), and the black pigment (F) in a stirrer such that the components are uniformly mixed into a solution state. When needed, the additive (G) can also be added. After the components are uniformly mixed, a photosensitive resin composition in a solution state can be obtained.

In addition, the method for preparing the photosensitive resin composition is not particularly limited. The method for preparing the photosensitive resin composition includes, for instance, first dispersing a portion of the alkali-soluble resin (A) and the compound (B) having an ethylenically unsaturated group in a portion of the solvent (E) to form a dispersion solution, and then mixing the rest of the alkali-soluble resin (A), the compound (B) having an ethylenically unsaturated group, the photoinitiator (C), the hyperbranched polymer (D), the solvent (E), and the black pigment (F).

Alternatively, the photosensitive resin composition can also be prepared by first dispersing a portion of the black pigment (F) in a mixture composed of a portion of the alkali-soluble resin (A) and a portion of the solvent (E) to form a black pigment dispersion liquid, and then adding the alkali-soluble resin (A), the compound (B) having an ethylenically unsaturated group, the photoinitiator (C), the hyperbranched polymer (D), the solvent (E), and the black pigment (F). Moreover, the dispersion steps of the black pigment (F) can be performed by mixing with a mixer such as a beads mill or a roll mill.

### <Method for Manufacturing Black Matrix>

The method for manufacturing the black matrix includes applying the treatments of pre-bake, exposure, development, and post-bake to the photosensitive resin composition on a substrate in order. The black matrix is used for isolating each pixel layer. Moreover, when the film thickness of the black matrix is 1 m, the range of the optical density can be at least 3.0, preferably 3.2 to 5.5, and more preferably 3.5 to 5.5. The method for manufacturing the black matrix is described below.

First, the photosensitive resin composition in liquid state is uniformly coated on a substrate by a coating method such as spin coating or cast coating to form a coating film. Specific examples of the substrate include alkali-free glass, soda-lime glass, hard glass (Pyrex glass), silica glass, and glasses with a transparent conductive film attached thereto used for a liquid crystal display apparatus. Alternatively, the substrate can be a substrate (such as a silicon substrate) used for a photoelectric conversion apparatus such as a solid imaging device.

After the coating film is formed, most of the solvent is removed by drying under reduced pressure. Next, the remaining solvent is completely removed by a pre-bake method to form a pre-baked coating film. It should be mentioned that, the conditions for drying under reduced pressure and pre-bake vary according to the type and the ratio of each component. In general, drying under reduced pressure is performed at a pressure less than 200 mmHg for 1 second to 20 seconds, and the pre-bake is a heat treatment performed on the coating film at a temperature of 70° C. to 110° C. for 1 minute to 15 minutes.

Then, the pre-baked coating film is exposed with a photomask having a specific pattern. The light used in the exposure process is preferably an ultraviolet such as a g-ray, an h-ray, or an i-ray. In addition, the ultraviolet irradiation apparatus can be a(n) (ultra-)high pressure mercury lamp or a metal halide lamp.

Then, the exposed pre-baked coating film is immersed in a developing solution at a temperature of 23±2° C. to remove the unexposed portion of the pre-baked coating film and to form a specific pattern on the substrate.

The developing solution is, for instance, an alkali compound such as sodium hydroxide, potassium hydroxide, sodium carbonate, sodium hydrogen carbonate, potassium carbonate, potassium hydrogen carbonate, sodium silicate, sodium methyl silicate, ammonia solution, ethylamine, diethylamine, dimethylethylanolamine, tetramethylammonium hydroxide, tetraethylammonium hydroxide, choline, pyrrole, piperidine, or 1,8-diazabicyclo[5.4.0]-7-undecene. The concentration of the developing solution is generally 0.001 wt % to 10 wt %, preferably 0.005 wt % to 5 wt %, and more preferably 0.01 wt % to 1 wt %.

After the pre-baked coating film is developed, the substrate having a specific pattern is rinsed with water, and then the specific pattern is air dried with compressed air or compressed nitrogen. Then, a post-bake treatment is performed with a heating device such as a hot plate or an oven. The post-bake temperature is generally 150 to 250° C., wherein the heating time when using the hot plate is 5 minutes to 60 minutes and the heating time when using the oven is 15 minutes to 150 minutes. After the treatment steps, a black matrix can be formed on the substrate.

### <Method for Manufacturing Pixel Layer and Color Filter>

The method for manufacturing the pixel layer is similar to the method for manufacturing the black matrix. Specifically, the pixel layer is obtained by coating the photosensitive composition for a color filter on the substrate on which a black matrix is formed, and then applying the treatments of pre-bake, exposure, development, and post-bake in order. However, drying under reduced pressure is performed at a pressure of 0 mmHg to 200 mmHg for 1 second to 60 seconds. After the treatment steps, a specific pattern can be fixed, thereby forming the pixel layer. Moreover, the steps are repeated to form pixel layers of, for instance, red, green, and blue on the substrate in order so as to obtain a substrate (i.e., color filter having pixel layers) on which a black matrix and pixel layers are formed.

### <Method for Manufacturing Liquid Crystal Display Apparatus>

First, the color filter formed by the method for manufacturing a color filter and a substrate provided with a thin film transistor (TFT) are disposed opposite to each other, and a gap (cell gap) is left between the two. Then, the color filter and the peripheral portion of the substrate are laminated with an adhesive and an injection hole is left. Then, liquid crystal is injected into the gap separated by the substrate surface and the adhesive through the injection hole. Lastly, the injection hole is sealed to form a liquid crystal layer. Then, a polarizer is provided to each of the other side of the color filter in contact with the liquid crystal layer and the other side of the substrate in contact with the liquid crystal layer to fabricate the liquid crystal apparatus. The liquid crystal used, i.e., a liquid crystal compound or a liquid crystal composition, is not particularly limited. Any liquid crystal compound or liquid crystal composition can be used.

Moreover, the liquid crystal alignment film used in the fabrication of the color filter is used to limit the alignment of the liquid crystal molecules and is not particularly limited. Both inorganic matter and organic matter can be used, and the invention is not limited thereto.

### Preparation Examples of Diol Compound (a-1) Containing a Polymeric Unsaturated Group

Preparation example 1 to preparation example 6 of the diol compound (a-1) containing a polymeric unsaturated group are described below:

### Preparation Example 1

First, 100 parts by weight of a fluorene epoxy compound (model number: ESF-300, made by Nippon Steel Chemical, epoxy equivalent: 231), 30 parts by weight of acrylic acid, 0.3 parts by weight of benzyltriethylammonium chloride, 0.1 parts by weight of 2,6-di-tert-butyl-p-cresol, and 130 parts by weight of propylene glycol monomethyl ether acetate were added in a 500 ml four-necked flask via a method of continuous addition. The feeding speed was controlled at 25 parts by weight/minute, the temperature of the reaction process was maintained at 100° C. to 110° C., and the mixture was reacted for 15 hours to obtain a light yellow transparent mixture solution having a solid content of 50 wt %. Then, steps of extraction, filtration, and heating and drying were performed on the light yellow transparent mixture solution to obtain a diol compound (a-1-1) containing a polymeric unsaturated group of preparation example 1 having a solid content of 99.9 wt %.

### Preparation Example 2

First, 100 parts by weight of a fluorene epoxy compound (model number: PG-100, made by Osaka Gas, epoxy equivalent: 259), 35 parts by weight of methacrylic acid, 0.3 parts by weight of benzyltriethylammonium chloride, 0.1 parts by weight of 2,6-di-tert-butyl-p-cresol, and 135 parts by weight of propylene glycol monomethyl ether acetate were added in a 500 ml four-necked flask via a method of continuous addition. The feeding speed was controlled at 25 parts by weight/minute, the temperature of the reaction process was maintained at 100° C. to 110° C., and the mixture was reacted for 15 hours to obtain a light yellow transparent mixture solution having a solid content of 50 wt %. Steps of extraction, filtration, and heating and drying were performed on the light yellow transparent mixture solution to obtain a diol compound (a-1-2) containing a polymeric unsaturated group of preparation example 2 having a solid content of 99.9 wt %.

### Preparation Example 3

100 parts by weight of a fluorene epoxy compound (model number: ESF-300, made by Nippon Steel Chemical, epoxy equivalent: 231), 100 parts by weight of 2-methacryloyloxyethyl succinate, 0.3 parts by weight of benzyltriethylammonium chloride, 0.1 parts by weight of 2,6-di-tert-butyl-p-cresol, and 200 parts by weight of propylene glycol monomethyl ether acetate were added in a 500 ml four-necked flask via a method of continuous addition. The feeding speed was controlled at 25 parts by weight/minute, the temperature of the reaction process was maintained at 100° C. to 110° C., and the mixture was reacted for 15 hours to obtain a light yellow transparent mixture solution having a solid content of 50 wt %. Steps of extraction, filtration, and heating and drying were performed on the light yellow transparent mixture solution to obtain a diol compound (a-1-3) containing a polymeric unsaturated group of preparation example 3 having a solid content of 99.9 wt %.

### Preparation Example 4

First, 0.3 moles of bis(4-hydroxyphenyl)sulfone, 9 moles of epichlorohydrin, and 0.003 moles of tetramethyl ammonium chloride were added in a 1000 mL three-necked flask provided with a mechanical stirrer, a thermometer, and a reflux condenser. Next, the flask was heated to 105° C. while stirring and reacted at 105° C. for 9 hours. Then, unreacted epichlorohydrin was distilled off under reduced pressure. Next, the reaction system was cooled to room temperature and 9 moles of benzene and 0.5 moles of sodium hydroxide (30 wt % aqueous solution formed by dissolving in water) were added thereto while stirring. Then, the temperature was raised to 60° C. and maintained at 60° C. for 3 hours. Next, the reaction solution was washed with water repeatedly until no chloride ions remained (tested with silver nitrate). The solvent benzene was removed via distillation under reduced pressure, and then the reaction solution was dried at 75° C. for 24 hours to obtain an epoxy compound of bis(4-hydroxyphenyl)sulfone.

100 parts by weight of an epoxy compound (epoxy equivalent 181) of bis(4-hydroxyphenyl)sulfone, 30 parts by weight of acrylic acid, 0.3 parts by weight of benzyltriethylammonium chloride, 0.1 parts by weight of 2,6-di-tert-butyl-p-cresol, and 130 parts by weight of propylene glycol monomethyl ether acetate were added in a 500 ml four-necked flask via a method of continuous addition. The feeding speed was controlled at 25 parts by weight/minute, the temperature of the reaction process was maintained at 100° C. to 110° C., and the mixture was reacted for 15 hours to obtain a light yellow transparent mixture solution having a solid content of 50 wt %. Steps of extraction, filtration, and heating and drying were performed on the light yellow transparent mixture solution to obtain a diol compound (a-1-4) containing a polymeric unsaturated group of preparation example 4 having a solid content of 99.9 wt %.

### Preparation Example 5

0.3 moles of bis(4-hydroxyphenyl)hexafluoropropane, 9 moles of epichlorohydrin, and 0.003 moles of tetramethyl ammonium chloride were added in a 1000 mL three-necked flask provided with a mechanical stirrer, a thermometer, and a reflux condenser. Next, the flask was heated to 105° C. while stirring and reacted at 105° C. for 9 hours. Then, unreacted epichlorohydrin was distilled off under reduced pressure. Next, the reaction system was cooled to room temperature and 9 moles of benzene and 0.5 moles of sodium hydroxide (30 wt % aqueous solution formed by dissolving in water) were added thereto while stirring. Then, the temperature was raised to 60° C. and maintained at 60° C. for 3 hours. Next, the reaction solution was washed with water repeatedly until no chloride ions remained (tested with silver nitrate). The solvent benzene was removed via distillation under reduced pressure, and then the reaction solution was dried at 75° C. for 24 hours to obtain an epoxy compound of bis(4-hydroxyphenyl)hexafluoropropane.

100 parts by weight of an epoxy compound (epoxy equivalent: 224) of bis(4-hydroxyphenyl)hexafluoropropane, 35 parts by weight of methacrylic acid, 0.3 parts by weight of benzyltriethylammonium chloride, 0.1 parts by weight of 2,6-di-tert-butyl-p-cresol, and 135 parts by weight of propylene glycol monomethyl ether acetate were added in a 500 ml four-necked flask via a method of continuous addition. The feeding speed was controlled at 25 parts by weight/minute, the temperature of the reaction process was maintained at 100° C. to 110° C., and the mixture was reacted for 15 hours to obtain a light yellow transparent mixture solution having a solid content of 50 wt %. Steps of extraction, filtration, and heating and drying were performed on the light yellow transparent mixture solution to obtain a diol compound (a-1-5) containing a polymeric unsaturated group of preparation example 5 having a solid content of 99.9 wt %.

### Preparation Example 6

0.3 moles of bis(4-hydroxyphenyl)dimethylsilane, 9 moles of epichlorohydrin, and 0.003 moles of tetramethyl ammonium chloride were added in a 1000 mL three-necked flask provided with a mechanical stirrer, a thermometer, and a reflux condenser. Next, the flask was heated to 105° C. while stirring and reacted at 105° C. for 9 hours. Then, unreacted epichlorohydrin was distilled off under reduced pressure. Next, the reaction system was cooled to room temperature and 9 moles of benzene and 0.5 moles of sodium hydroxide (30 wt % aqueous solution formed by dissolving in water) were added thereto while stirring. Then, the temperature was raised to 60° C. and maintained at 60° C. for 3 hours. Next, the reaction solution was washed with water repeatedly until no chloride ions remained (tested with silver nitrate). The solvent benzene was removed via distillation under reduced pressure, and then the reaction solution was dried at 75° C. for 24 hours to obtain an epoxy compound of bis(4-hydroxyphenyl)dimethylsilane.

100 parts by weight of an epoxy compound (epoxy equivalent: 278) of bis(4-hydroxyphenyl)dimethylsilane, 100 parts by weight of 2-methacryloyl oxyethyl succinate, 0.3 parts by weight of benzyltriethylammonium chloride, 0.1 parts by weight of 2,6-di-tert-butyl-p-cresol, and 200 parts by weight of propylene glycol monomethyl ether acetate were added in a 500 ml four-necked flask via a method of continuous addition. The feeding speed was controlled at 25 parts by weight/minute, the temperature of the reaction process was maintained at 100° C. to 110° C., and the mixture was reacted for 15 hours to obtain a light yellow transparent mixture solution having a solid content of 50 wt %. Steps of extraction, filtration, and heating and drying were performed on the light yellow transparent mixture solution to obtain a diol compound (a-1-6) containing a polymeric unsaturated group of preparation example 6 having a solid content of 99.9 wt %.

### Synthesis Examples of First Alkali-Soluble Resin (A-1)

In the following, synthesis example A-1-1 to synthesis example A-1-10 of the first alkali-soluble resin A-1 are described:

### Synthesis Example A-1-1

First, 1.0 mole of the diol compound containing a polymeric unsaturated group (a-1-1), 0.1 moles of 4,4′-hexafluoro isopropylidene diphthalic dianhydride (a-2-1-a), 0.2 moles of pyromellitic dianhydride (a-2-2-c), 0.4 moles of maleic acid (a-3-2-a), 1.0 mole of tetrahydrophthalic anhydride (a-3-2-b), 1.9 grams of benzyltriethylammonium chloride, 0.6 grams of 2,6-di-tert-butyl-p-cresol, and 750 grams of propylene glycol monomethyl ether acetate were added in a 500 mL four-necked flask at the same time to form a reaction solution. Here, “simultaneous addition” refers to adding the tetracarboxylic acid or an acid dianhydride thereof (a-2) and the dicarboxylic acid or an acid anhydride thereof (a-3) at the same reaction time. Then, the reaction solution was heated to 110° C. and reacted for 2 hours to obtain the first alkali-soluble resin A-1-1 having an acid value of 129 mgKOH/g and a number-average molecular weight of 2368.

### Synthesis Example A-1-2

1.0 mole of the diol compound (a-1-2) containing a polymeric unsaturated group, 2.0 grams of benzyltriethylammonium chloride, 0.7 grams of 2,6-di-tert-butyl-p-cresol, and 700 grams of propylene glycol monomethyl ether acetate were added in a 500 mL four-necked flask to form a reaction solution. Then, 0.2 moles of 1,4-difluoropyromellitic dianhydride (a-2-1-b) and 0.2 moles of benzophenone tetracarboxylic dianhydride (a-2-2-b) were added and the mixture was reacted at 90° C. for 2 hours. Then, 1.2 moles of tetrahydrophthalic anhydride (a-3-2-b) was added and the mixture was reacted at 90° C. for 4 hours. Here, “successive addition” refers to respectively adding the tetracarboxylic acid or an acid dianhydride thereof (a-2) and the dicarboxylic acid or an acid anhydride thereof (a-3) at different reaction times. That is, the tetracarboxylic acid or an acid dianhydride thereof (a-2) was added first, and the dicarboxylic acid or an acid anhydride thereof (a-3) was added afterward. After the synthesis steps, the first alkali-soluble resin A-1-2 having an acid value of 125 mgKOH/g and a number-average molecular weight of 3388 was obtained.

### Synthesis Example A-1-3, Synthesis Example A-1-5, Synthesis Example A-1-7, and Synthesis Example A-1-9

The first alkali-soluble resins of synthesis example A-1-3, synthesis example A-1-5, synthesis example A-1-7, and synthesis example A-1-9 were prepared with the same steps as synthesis example A-1-1, and the difference thereof is: the type, the usage amount, the reaction time, the reaction temperature, and the addition time of the reactants of the components of the first alkali-soluble resins were changed (as shown in Table 1).

### Synthesis Example A-1-4, Synthesis Example A-1-6, Synthesis Example A-1-8, and Synthesis Example A-1-10

The first alkali-soluble resins of synthesis example A-1-4, synthesis example A-1-6, synthesis example A-1-8, and synthesis example A-1-10 were prepared with the same steps as synthesis example A-1-2, and the difference thereof is: the type, the usage amount, the reaction time, the reaction temperature, and the addition time of the reactants of the components of the first alkali-soluble resins were changed (as shown in Table 1).

The compounds corresponding to the abbreviations in Table 1 and Table 2 are as shown below.

| Abbre- | |
|---|---|
| viation | Component |
| a-1-1 | Diol compound (a-1-1) containing a polymeric unsaturated |
| | group of preparation example 1 |
| a-1-2 | Diol compound (a-1-2) containing a polymeric unsaturated |
| | group of preparation example 2 |
| a-1-3 | Diol compound (a-1-3) containing a polymeric unsaturated |
| | group of preparation example 3 |
| a-1-4 | Diol compound (a-1-4) containing a polymeric unsaturated |
| | group of preparation example 4 |
| a-1-5 | Diol compound (a-1-5) containing a polymeric unsaturated |
| | group of preparation example 5 |
| a-1-6 | Diol compound (a-1-6) containing a polymeric unsaturated |
| | group of preparation example 6 |
| a-2-1-a | 4,4′-hexafluoro isopropylidene diphthalic dianhydride |
| | (6FDA) |
| a-2-1-b | 1,4-difluoropyromellitic dianhydride |
| a-2-1-c | 1,4-difluoropyromellitic dianhydride |
| a-2-1-d | 1,4-bis(3,4-dicarboxytrifluorophenoxy)tetrafluoro |
| | benzenedianhydride |
| a-2-2-a | Biphenyl tetracarboxylic acid |
| a-2-2-b | Benzophenone tetracarboxylic dianhydride |
| a-2-2-c | Pyromellitic dianhydride |
| a-3-1-a | 3-fluorophthalic anhydride |
| a-3-1-b | 3,6-difluorophthalic anhydride |
| a-3-1-c | 4-fluorophthalic anhydride |
| a-3-1-d | Tetrafluorobutanedioic anhydride |
| a-3-2-a | Maleic acid |
| a-3-2-b | Tetrahydrophthalic anhydride |
| PGMEA | Propylene glycol monomethyl ether acetate (PGMEA) |
| EEP | Ethyl 3-ethoxypropionate (EEP) |
| — | Benzyltriethylammonium chloride |
| — | 2,6-di-tert-butyl-p-cresol |

TABLE 1

| | | | | Synthesis example | | | | |
|---|---|---|---|---|---|---|---|---|
| Component | | | | A-1-1 | A-1-2 | A-1-3 | A-1-4 | A-1-5 |
| Polymeric | Diol compound (a-1) containing a polymeric | | a-1-1 | 1.0 | — | — | — | — |
| component | unsaturated group (moles) | | a-1-2 | — | 1.0 | — | — | — |
| | | | a-1-3 | — | — | 1.0 | — | — |
| | | | a-1-4 | — | — | — | 1.0 | — |
| | | | a-1-5 | — | — | — | — | 1.0 |
| | | | a-1-6 | — | — | — | — | — |
| | Tetracarboxylic | Tetracarboxylic acid or an | a-2-1-a | 0.1 | — | — | — | — |
| | acid or an acid | acid dianhydride thereof | a-2-1-b | — | 0.2 | — | — | — |
| | dianhydride thereof | (a-2-1) containing a fluorine | a-2-1-c | — | — | 0.1 | — | — |
| | (a-2) | atom | a-2-1-d | — | — | 0.2 | 0.6 | — |
| | | Other tetracarboxylic acids | a-2-2-a | — | — | 0.3 | — | 0.4 |
| | | or an acid dianhydride | a-2-2-b | — | 0.2 | — | — | — |
| | | thereof (a-2-2) | a-2-2-c | 0.2 | — | — | — | — |
| | Dicarboxylic acid or | Dicarboxylic acid or an acid | a-3-1-a | — | — | — | — | 1.2 |
| | an acid anhydride | anhydride thereof (a-3-1) | a-3-1-b | — | — | — | — | — |
| | thereof (a-3) | containing a fluorine atom | a-3-1-c | — | — | — | — | — |
| | | | a-3-1-d | — | — | — | — | — |
| | | Other dicarboxylic acids or | a-3-2-a | 0.4 | — | — | 0.8 | — |
| | | an acid anhydride thereof | a-3-2-b | 1.0 | 1.2 | 0.8 | — | — |
| | | (a-3-2) | | | | | | |

| Monomer input method | | simultaneous | successive | simultaneous | successive | simultaneous |
|---|---|---|---|---|---|---|
| | | addition | addition | addition | addition | addition |
| Catalyst | Benzyltriethylammonium chloride (grams) | 1.9 | 2.0 | 2.9 | 1.1 | 1.3 |
| Inhibitor | 2,6-di-tert-butyl-p-cresol (grams) | 0.6 | 0.7 | 1.0 | 0.4 | 0.4 |
| Solvent | PGMEA (grams) | 750 | 700 | 1000 | — | 650 |
| | EEP (grams) | — | — | 100 | 650 | — |

| [(a-2-1) + (a-3-1)]/(a-1) | | | | 0.1 | 0.2 | 0.3 | 0.6 | 1.2 |
|---|---|---|---|---|---|---|---|---|
| Reaction temperature (° C.) | | | | 110 | 90 | 115 | 95 | 110 |
| Reaction time (hours) | | | | 2 | 2 | 1.5 | 1.5 | 2 |
| | | | | | 4 | | 4 | |
| Acid value (mgKOH/g) | | | | 129 | 125 | 87 | 139 | 144 |
| Number-average molecular weight (Mn) | | | | 2368 | 3388 | 4965 | 5201 | 3665 |
| | | | | Synthesis example | | | | |
| Component | | | | A-1-6 | A-1-7 | A-1-8 | A-1-9 | A-1-10 |
| Polymeric | Diol compound (a-1) containing a polymeric | | a-1-1 | — | 1.0 | — | 0.5 | — |
| component | unsaturated group (moles) | | a-1-2 | — | — | — | — | 0.5 |
| | | | a-1-3 | — | — | 1.0 | 0.3 | 0.5 |
| | | | a-1-4 | — | — | — | 0.2 | — |
| | | | a-1-5 | — | — | — | — | — |
| | | | a-1-6 | 1.0 | — | — | — | — |
| | Tetracarboxylic | Tetracarboxylic acid or an | a-2-1-a | — | — | — | 0.2 | — |
| | acid or an acid | acid dianhydride thereof | a-2-1-b | — | — | — | — | — |
| | dianhydride thereof | (a-2-1) containing a | a-2-1-c | — | — | — | — | — |
| | (a-2) | fluorine atom | a-2-1-d | — | — | — | — | 0.3 |
| | | Other tetracarboxylic acids | a-2-2-a | — | — | — | 0.5 | — |
| | | or an acid dianhydride | a-2-2-b | 0.1 | — | — | — | 0.5 |
| | | thereof (a-2-2) | a-2-2-c | — | 0.1 | — | — | — |
| | Dicarboxylic acid | Dicarboxylic acid or an | a-3-1-a | — | 1.2 | — | — | — |
| | or an acid | acid anhydride thereof | a-3-1-b | 1.6 | — | — | 0.6 | — |
| | anhydride thereof | (a-3-1) containing a | a-3-1-c | — | 0.6 | — | — | 0.2 |
| | (a-3) | fluorine atom | a-3-1-d | — | — | 1.9 | — | — |
| | | Other dicarboxylic acids or | a-3-2-a | — | — | — | — | 0.2 |
| | | an acid anhydride thereof | a-3-2-b | 0.2 | — | 0.1 | — | — |
| | | (a-3-2) | | | | | | |

| Monomer input method | | successive | simultaneous | successive | simultaneous | successive |
|---|---|---|---|---|---|---|
| | | addition | addition | addition | addition | addition |
| Catalyst | Benzyltriethylammonium chloride (grams) | 1.1 | 1.9 | 2.9 | 2.0 | 2.4 |
| Inhibitor | 2,6-di-tert-butyl-p-cresol (grams) | 0.4 | 0.6 | 1.0 | 0.7 | 0.8 |
| Solvent | PGMEA (grams) | 600 | 800 | 1100 | — | 100 |
| | EEP (grams) | — | — | — | 850 | 900 |

| | | | | | |
|---|---|---|---|---|---|
| [(a-2-1) + (a-3-1)]/(a-1) | 1.6 | 1.8 | 1.9 | 0.8 | 0.5 |
| Reaction temperature (° C.) | 90 | 115 | 95 | 110 | 90 |
| Reaction time (hours) | 2 | 1.5 | 2 | 2 | 2 |
| | 3.5 | | 3.5 | | 4 |
| Acid value (mgKOH/g) | 159 | 113 | 87 | 108 | 93 |
| Number-average molecular weight (Mn) | 1885 | 1732 | 1250 | 6023 | 6802 |

### Synthesis Examples of Second Alkali-Soluble Resin (A-2)

In the following, synthesis example A-2-1 to synthesis example A-2-3 of the second alkali-soluble resin (A-2) are described:

### Synthesis Example A-2-1

1.0 mole of the diol compound (a-1-1) containing a polymeric unsaturated group, 1.9 grams of benzyltriethylammonium chloride, and 0.6 grams of 2,6-di-tert-butyl-p-cresol were dissolved in 700 grams of propylene glycol monomethyl ether acetate, and 0.3 moles of biphenyl tetracarboxylic acid (a-2-2-a) and 1.4 moles of maleic acid (a-3-2-a) were added at the same time. Then, the mixture was heated to 110° C. and reacted for 2 hours to obtain the second alkali-soluble resin A-2-1 having an acid value of 125 mgKOH/g and a number-average molecular weight of 2455.

### Synthesis Example A-2-2

The second alkali-soluble resin of synthesis example A-2-2 was prepared with the same steps as synthesis example A-2-1, and the difference thereof is: the type, the usage amount, the reaction time, the reaction temperature, and the addition time of the reactants of the components of the second alkali-soluble resin were changed (as shown in Table 2). It should be mentioned that, here, “simultaneous addition” refers to adding the tetracarboxylic acid or an acid dianhydride thereof (a-2) and the dicarboxylic acid or an acid anhydride thereof (a-3) at the same reaction time, and “successive addition” refers to respectively adding the tetracarboxylic acid or an acid dianhydride thereof (a-2) and the dicarboxylic acid or an acid anhydride thereof (a-3) at different reaction times. That is, the tetracarboxylic acid or an acid dianhydride thereof (a-2) was added first, and the dicarboxylic acid or an acid anhydride thereof (a-3) was added afterward.

TABLE 2

| | | | | Synthesis example | |
|---|---|---|---|---|---|
| Component | | | | A-2-1 | A-2-2 |
| Polymeric | Diol compound (a-1) containing a | | a-1-1 | 1.0 | — |
| component | polymeric unsaturated group | | a-1-2 | — | — |
| | (moles) | | a-1-3 | — | 1.0 |
| | | | a-1-4 | — | — |
| | | | a-1-5 | — | — |
| | | | a-1-6 | — | — |
| | Tetracarboxylic | Tetracarboxylic | a-2-1-a | — | — |
| | acid or an acid | acid or an acid | a-2-1-b | — | — |
| | dianhydride | dianhydride thereof | a-2-1-c | — | — |
| | thereof (a-2) | (a-2-1) containing a | a-2-1-d | — | — |
| | | fluorine atom | | | |
| | | Other | a-2-2-a | 0.3 | — |
| | | tetracarboxylic | a-2-2-b | — | 0.6 |
| | | acids or an acid | a-2-2-c | — | — |
| | | dianhydride thereof | | | |
| | | (a-2-2) | | | |
| | Dicarboxylic | Dicarboxylic | a-3-1-a | — | — |
| | acid or an acid | acid or an acid | a-3-1-b | — | — |
| | anhydride | anhydride thereof | a-3-1-c | — | — |
| | thereof (a-3) | (a-3-1) containing a | a-3-1-d | — | — |
| | | fluorine atom | | | |
| | | Other dicarboxylic | a-3-2-a | 1.4 | — |
| | | acids or an acid | a-3-2-b | — | 0.8 |
| | | anhydride thereof | | | |
| | | (a-3-2) | | | |

| Monomer input method | | simultaneous | successive |
|---|---|---|---|
| | | addition | addition |
| Catalyst | Benzyltriethylammonium chloride (grams) | 1.9 | 2.9 |
| Inhibitor | 2,6-di-tert-butyl-p-cresol (grams) | 0.6 | 0.0 |
| Solvent | PGMEA (grams) | 700 | 950 |
| | EEP (grams) | — | — |

| | | |
|---|---|---|
| (a-2)/(a-1) | 0 | 0 |
| (a-3)/(a-1) | 0 | 0 |
| Reaction temperature (° C.) | 110 | 90 |
| Reaction time (hours) | 2 | 2 |
| | | 4 |
| Acid value (mgKOH/g) | 125 | 92 |
| Number-average molecular weight (Mn) | 2455 | 5130 |

### Synthesis Examples of Other Alkali-Soluble Resins (A-3)

In the following, synthesis example A-3-1 to synthesis example A-3-3 of the other alkali-soluble resins (A-3) are described:

### Synthesis Example A-3-1

A nitrogen inlet, a stirrer, a heater, a condenser tube, and a thermometer were provided to a four-necked flask having a volume of 1000 ml. After nitrogen was introduced, 30 parts by weight of 2-hydroxyethyl methacrylate (HEMA), 10 parts by weight of benzyl methacrylate (BzMA), 60 parts by weight of CF9BuMA, 3 parts by weight of 2,2′-azobis(2-methylbutyronitrile) (AMBN), and 300 parts by weight of diethylene glycol dimethyl ether (diglyme) were added. Then, the mixture was slowly stirred and the solution was heated to 80° C. Then, polycondensation was performed on the mixture at 80° C. for 6 hours. Then, after the solvent was evaporated, the other alkali-soluble resins (A-3-1) were obtained.

### Synthesis Example A-3-2 to Synthesis Example A-3-3

The other alkali-soluble resins of synthesis example A-3-2 to synthesis example A-3-3 were prepared with the same steps as synthesis example A-3-1, and the difference thereof is: the type, the usage amount, the reaction time, the reaction temperature, and the addition time of the reactants of the components of the other alkali-soluble resins were changed (as shown in Table 3), wherein the compounds corresponding to the abbreviations in Table 3 are as follows.

| Abbre- | |
|---|---|
| viation | Component |
| AMBN | 2,2′-azobis-2-methyl butyronitrile |
| ADVN | 2,2′-azobis(2,4-dimethylvaleronitrile) |
| MAA | Methacrylic acid |
| GMA | Glycidyl methacylate |
| HEMA | 2-hydroxyethyl methacrylate |
| BzMA | Benzyl methacrylate |
| IBOMA | Isobornyl methacrylate |
| CF9BuMA | CH₂═C(CH₃)COOCH₂CH₂CH₂CH₂OC₉F₁₇ |
| CF9PEMA | CH₂═C(CH₃)COOCH₂CH₂OCOC6H4OC₉F₁₇ |
| Diglyme | Diethylene glycol dimethyl ether |
| PGMEA | Propylene glycol monomethyl ether acetate |

### Synthesis Examples of Hyperbranched Polymer (D)

TABLE 3

| | | Synthesis example | | |
|---|---|---|---|---|
| Component | | A-3-1 | A-3-2 | A-3-3 |
| Monomer | MAA | — | 20 | 30 |
| (parts by | GMA | — | — | 10 |
| weight) | HEMA | 30 | — | — |
| | BzMA | 10 | — | 40 |
| | IBOMA | — | 10 | 40 |
| Fluorine-containing | CF9BuMA | 60 | — | — |
| monomer | CF9PEMA | — | 60 | — |
| (parts by | | | | |
| weight) | | | | |
| Solvent (parts | Diglyme | 300 | — | 300 |
| by weight) | PGMEA | — | 300 | — |
| Initiator (parts | AMBN | 3.0 | 3.0 | — |
| by weight) | ADVN | — | — | 2.0 |

| | | | |
|---|---|---|---|
| Reaction temperature (° C.) | 80 | 80 | 80 |
| Polycondensation time (hours) | 6 | 6 | 6 |

In the following, synthesis example D-1 to synthesis example D-3 of the hyperbranched polymer (D) are described:

### Synthesis Example D-1

In a four-necked flask having a volume of 1 L, 25 g of trimethylolpropane tri(mercaptoacetate) (mercapto group: 0.28 moles), 177 g of pentaerythritol tetraacrylate (carbon-carbon double bond: 2.01 moles), 0.1 g of hydroquinone, and 0.01 g of benzyl dimethyl amine (used as photoinitiator) were added, and the mixture was reacted at 60° C. for 12 hours. For each reaction product, the disappearance of the mercapto group was confirmed via an iodine titration method to obtain the hyperbranched polymer D-1. The molecular weight of the hyperbranched polymer D-1 measured via gel filtration chromatography was 4,400.

### Synthesis Example D-2

In a four-necked flask having a volume of 1 L, 20 g of pentaerythritol tetra(mercaptoacetate) (mercapto group: 0.19 moles), 212 g of a mixture (carbon-carbon double bond: 2.12 moles) of dipentaerythritol hexacrylate and dipentaerythritol pentaacrylate, 0.1 g of hydroquinone, and 0.01 g of benzyl dimethyl amine were added, and the mixture was reacted at 60° C. for 12 hours. For each reaction product, the disappearance of the mercapto group was confirmed via an iodine titration method to obtain the hyperbranched polymer D-2. The molecular weight of the hyperbranched polymer D-2 measured via gel filtration chromatography was 11,000.

### Synthesis Example D-3

In a four-necked flask having a volume of 1 L, 20 g of pentaerythritol tetra(mercaptoacetate) (mercapto group: 0.19 moles), 212 g of a mixture (carbon-carbon double bond: 2.12 moles) of dipentaerythritol hexacrylate and dipentaerythritol pentaacrylate, 58 g of propylene glycol monomethyl ether acetate (used as solvent), 0.1 g of hydroquinone, and 0.01 g of benzyl dimethyl amine were added, and the mixture was reacted at 60° C. for 12 hours. For each reaction product, the disappearance of the mercapto group was confirmed via an iodine titration method to obtain an intermediate product. The molecular weight of the intermediate product measured via gel filtration chromatography was 11,000.

Next, in the four-necked flask, 20 g (0.22 moles) of thioglycolic acid was added, and the mixture was reacted at 60° C. for 12 hours. For each reaction product, the disappearance of the mercapto group was confirmed via an iodine titration method to obtain the hyperbranched polymer D-3. The molecular weight of the hyperbranched polymer D-3 measured via gel filtration chromatography was 12,000.

### Examples of photosensitive resin

Example 1 to example 10 and comparative example 1 to comparative example 6 of the photosensitive resin are described below:

### Example 1

### a. Photosensitive Resin Composition

100 parts by weight of the first alkali-soluble resin A-1-1, 15 parts by weight of an esterified compound (hereinafter B-1-1) of pentaerythritol triacrylate and phthalic acid, 5 parts by weight of ethanone, 1-[9-ethyl-6-(2-methylbenzoyl)-9H-carbazole-3-yl]-,1-(O-acetyl oxime) (hereinafter C-1), 5 parts by weight of the hyperbranched polymer D-1 (hereinafter D-1), and 60 parts by weight of C.I. Pigment BK7 (hereinafter F-1) were added to 1000 parts by weight of propylene glycol monomethyl ether acetate (hereinafter E-1). After the mixture was uniformly stirred via a shaking-type stirrer, the photosensitive resin composition of example 1 was obtained.

### b. Forming of Film

The photosensitive resin composition of example 1 was coated on a plain glass substrate (dimension: 100 mm×100 mm×0.7 mm) via a spin coating method to form a coating film having a thickness of about 6 μm. Next, the coating film was pre-baked at 90° C. for 2 minutes to 3 minutes. Then, a photomask was disposed between an exposure machine and the coating film, and patterning exposure was performed on the pre-baked coating film via 100 mJ/cm² of ultraviolet light (model of exposure machine: AG500-4N, made by M&R Nanotechnology). The exposed coating film was immersed in a 0.05% aqueous potassium hydroxide solution for 45 seconds to 90 seconds to remove the undesired portion of the exposed coating film. Next, the plain glass substrate was rinsed with water. Lastly, post-bake was performed on the coating film at 235° C. in an oven for 30 minutes to obtain a glass substrate on which the film of example 1 was formed. The film of example 1 was evaluated by each of the following evaluation methods, and the results thereof are as shown in Table 4.

### Example 2 to example 10

The photosensitive resin compositions and the films of example 2 to example 10 were prepared with the same steps as example 1, and the difference thereof is: the type and the usage amount of the components of the photosensitive resin compositions were changed (as shown in Table 4), wherein the compounds corresponding to the abbreviations in Table 4 are as shown below. The obtained films were evaluated by each of the following evaluation methods, and the results thereof are as shown in Table 4.

The compounds corresponding to the labels in Table 4 and Table 5 are as shown below.

| Abbre- | |
|---|---|
| viation | Component |
| B-1-1 | Esterified compound of pentaerythritol triacrylate and phthalic |
| | acid |
| B-1-2 | Esterified compound of dipentaerythritol |
| | penta(methyl methacrylate) and succinic acid |
| B-2-1 | Trimethylolpropane triacrylate |
| B-2-2 | Dipentaerythritol hexacrylate |
| C-1 | Ethanone, 1-[9-ethyl-6-(2-methylbenzoyl)-9H-carbazole-3-yl]-, |
| | 1-(O-acetyl oxime) (product name: OXE-02, made by Ciba |
| | Specialty Chemicals Co., Ltd.) |
| C-2 | 1-(4-phenyl-thio-phenyl)-octane-1,2-dion-2-oxime-O-benzoate |
| | (product name: OXE-01, made by Ciba Specialty |
| | Chemicals Co., Ltd.) |
| C-3 | 2-methyl-1-[4-(memylthio)phenyl]-2-morpholino-1-propanone |
| | (product name: IRGACURE 907, made by Ciba Specialty |
| | Chemicals Co., Ltd.) |
| D-1 | Hyperbranched polymer D-1 |
| D-2 | Hyperbranched polymer D-2 |
| D-3 | Hyperbranched polymer D-3 |
| E-1 | Propylene glycol monomethyl ether acetate |
| E-2 | Ethyl 3-ethoxypropionate |
| F-1 | C.I. Pigment BK7 |
| F-2 | MA100 (made by Mitsubishi Chemical) |
| G-1 | SF-8427 (made by Dow Corning Toray Co., Ltd., surfactant) |
| G-2 | 3-glycidoxypropyltrimethoxysilane (product name: |
| | KBM403, made by Shin-Etsu Chemical, adhesion promoter) |

### Comparative Example 1 to Comparative Example 6

The photosensitive resin compositions and the films of comparative example 1 to comparative example 6 were prepared using the same steps as example 1, and the difference thereof is: the type and the usage amount of the components of the photosensitive resin compositions were changed (as shown in Table 5). The obtained films were evaluated by each of the following evaluation methods, and the results thereof are as shown in Table 5.

### <Evaluation Methods>

a. Adhesion

The adhesion was evaluated according to the 8.5.2 cross-hatch test in 8.5 adhesion test of JIS K-5400-1990. The films obtained in the examples and the comparative examples were cut into 100 cross-hatches via a small knife. Next, an adhesive tape was adhered to the films and then peeled off to observe the remaining cross-hatches. A lesser number of fallen cross-hatches indicates better adhesion between the film and the substrate. The adhesion was evaluated according to the following evaluation criteria.
⊚: 0%≦number of fallen cross-hatches ≦3%
◯: 3%<number of fallen cross-hatches ≦5%
Δ: 5%<number of fallen cross-hatches ≦35%
X: 35%<number of fallen cross-hatches ≦100%
   b. Hardness

The pencil hardness of the films obtained in the examples and the comparative examples was evaluated according to the 8.4.1 pencil scratch test of JIS K-5400-1990. The hardness of the films was evaluated according to the following evaluation criteria.
⊚: 3H≦pencil hardness
◯: 1H≦pencil hardness <3H
Δ: HB≦pencil hardness <1H
X: pencil hardness <HB

TABLE 4

| Component | | | Example | | | | | | | | | |
|---|---|---|---|---|---|---|---|---|---|---|---|---|
| (parts by weight) | | | 1 | 2 | 3 | 4 | 5 | 6 | 7 | 8 | 9 | 10 |
| Alkali-soluble | A-1 | A-1-1 | 100 | — | — | — | — | — | — | — | — | — |
| resin (A) | | A-1-2 | — | 90 | — | — | — | — | — | — | — | — |
| | | A-1-3 | — | — | 80 | — | — | — | — | — | — | — |
| | | A-1-4 | — | — | — | 75 | — | — | — | — | — | — |
| | | A-1-5 | — | — | — | — | 70 | — | — | — | — | — |
| | | A-1-6 | — | — | — | — | — | 45 | — | — | — | — |
| | | A-1-7 | — | — | — | — | — | — | 30 | — | — | — |
| | | A-1-8 | — | — | — | — | — | — | — | 25 | — | — |
| | | A-1-9 | — | — | — | — | — | — | — | — | 15 | — |
| | | A-1-10 | — | — | — | — | — | — | — | — | — | 10 |
| | A-2 | A-2-1 | — | 10 | — | 25 | — | 40 | — | — | 85 | — |
| | | A-2-2 | — | — | 20 | — | 30 | — | 50 | 75 | — | 60 |
| | A-3 | A-3-1 | — | — | — | — | — | 15 | — | — | — | — |
| | | A-3-2 | — | — | — | — | — | — | 20 | — | — | — |
| | | A-3-3 | — | — | — | — | — | — | — | — | — | 30 |
| Compound (B) | B-1 | B-1-1 | 15 | — | — | — | — | — | — | — | — | — |
| containing an | | B-1-2 | — | 45 | — | — | — | 90 | — | — | 150 | — |
| ethylenically | B-2 | B-2-1 | — | — | — | 35 | 60 | — | 100 | — | — | 135 |
| unsaturated | | B-2-2 | — | — | 30 | — | — | — | — | 120 | 50 | — |
| group | | | | | | | | | | | | |

| | | | | | | | | | | | |
|---|---|---|---|---|---|---|---|---|---|---|---|
| Photoinitiator | C-1 | 5 | — | — | 15 | — | 30 | — | 40 | — | 35 |
| (C) | C-2 | — | 20 | — | — | 10 | — | — | — | 45 | — |
| | C-3 | — | — | 30 | 5 | — | — | 35 | — | — | 20 |
| Hyperbranched | D-1 | 5 | — | — | 20 | 32 | — | — | — | 15 | — |
| polymer (D) | D-2 | — | 3 | 26 | — | — | — | 35 | 10 | — | 10 |
| | D-3 | — | — | — | — | — | 10 | — | 15 | — | — |
| Solvent (E) | E-1 | 1000 | — | 1500 | — | 3000 | 1300 | — | 4600 | — | 2000 |
| | E-2 | — | 2700 | — | 2200 | — | 600 | 3800 | — | 5000 | 1300 |
| Black pigment | F-1 | 60 | — | 150 | — | 240 | — | 300 | — | 550 | — |
| (F) | F-2 | — | 85 | — | 200 | — | 320 | 100 | 470 | — | 600 |
| Additive | G-1 | — | 0.2 | — | — | — | — | — | — | — | — |
| | G-2 | — | — | — | — | — | — | — | 2 | — | — |
| Evaluation | Hardness | ⊚ | ⊚ | ◯ | ◯ | ◯ | ⊚ | ◯ | ⊚ | ⊚ | ◯ |
| results | Adhesion | ⊚ | ⊚ | ◯ | ⊚ | ⊚ | ⊚ | ◯ | ⊚ | ⊚ | ⊚ |

TABLE 5

| Component | | | Comparative example | | | | | |
|---|---|---|---|---|---|---|---|---|
| (parts by weight) | | | 1 | 2 | 3 | 4 | 5 | 6 |
| Alkali-soluble | A-1 | A-1-1 | — | — | — | — | 100 | — |
| resin (A) | | A-1-2 | — | — | — | — | — | — |
| | | A-1-3 | — | — | — | — | — | — |
| | | A-1-4 | — | — | — | — | — | — |
| | | A-1-5 | — | — | — | — | — | — |
| | | A-1-6 | — | — | — | — | — | — |
| | | A-1-7 | — | — | — | — | — | — |
| | | A-1-8 | — | — | — | — | — | — |
| | | A-1-9 | — | — | — | — | — | — |
| | | A-1-10 | — | — | — | — | — | — |
| | A-2 | A-2-1 | 100 | — | — | — | — | 100 |
| | | A-2-2 | — | 100 | — | — | — | — |
| | A-3 | A-3-1 | — | — | 100 | — | — | — |
| | | A-3-2 | — | — | — | — | — | — |
| | | A-3-3 | — | — | — | 100 | — | — |
| Compound (B) | B-1 | B-1-1 | — | — | — | — | — | — |
| containing an | | B-1-2 | — | — | — | — | — | — |
| ethylenically | B-2 | B-2-1 | 50 | — | 50 | — | 100 | — |
| unsaturated | | B-2-2 | — | 50 | — | 50 | — | 100 |
| group | | | | | | | | |

| | | | | | | | |
|---|---|---|---|---|---|---|---|
| Photoinitiator | C-1 | 25 | — | — | 25 | — | — |
| (C) | C-2 | — | 25 | — | — | 30 | — |
| | C-3 | — | — | 25 | — | — | 30 |
| Hyperbranched | D-1 | 20 | — | 20 | — | — | — |
| polymer (D) | D-2 | — | 20 | — | 20 | — | — |
| | D-3 | — | — | — | — | — | — |
| Solvent (E) | E-1 | 2500 | 2500 | — | — | 2500 | 2500 |
| | E-2 | — | — | 2500 | 2500 | — | — |
| Black pigment | F-1 | 200 | — | 250 | 250 | 250 | — |
| (F) | F-2 | — | 200 | — | — | — | 250 |
| Additive | G-1 | — | — | — | — | — | — |
| | G-2 | — | — | — | — | — | — |
| Evaluation | Hardness | ◯ | ◯ | ◯ | ◯ | X | X |
| results | Adhesion | X | X | X | X | X | X |

### <Evaluation Results>

It can be known from Table 4 and Table 5 that, in comparison to the films (example 1 to example 10) formed by the photosensitive resin composition containing the first alkali-soluble resin (A-1) (alkali soluble resin containing an aromatic structure having fluorine), the adhesion of the films (comparative example 1, comparative example 2, and comparative example 6) formed by the photosensitive resin composition only containing the second alkali soluble resin (A-2) and the films (comparative example 3 and comparative example 4) formed by the photosensitive resin composition only containing the other alkali soluble resins (A-3) is poor.

Moreover, in comparison to the films (example 1 to example 10) formed by the photosensitive resin composition containing the hyperbranched polymer (D), the hardness of the films (comparative example 5 and comparative example 6) formed by the photosensitive resin composition without the hyperbranched polymer (D) is poor.

Moreover, in the case that the hyperbranched polymer (D) contains a carboxyl group (example 6 and example 8), the adhesion and the hardness of the film formed by the photosensitive resin composition are better.

Moreover, in the case that the number of moles of the diol compound (a-1) containing a polymeric unsaturated group, the number of moles of the tetracarboxylic acid or an acid dianhydride thereof (a-2-1) containing a fluorine atom, and the number of moles of the dicarboxylic acid or an acid anhydride thereof (a-3-1) containing a fluorine atom in the first alkali-soluble resin (A-1) satisfy the relationship [(a-2-1)+(a-3-1)]/(a-1)=0.4-1.6 (i.e., example 4, example 5, example 6, example 9, and example 10), the adhesion of the film formed by the photosensitive resin composition is better.

Moreover, in the case that the compound (B) having an ethylenically unsaturated group contains the compound (B-1) having an acidic group and at least three ethylenically unsaturated groups (example 1, example 2, example 6, and example 9), the adhesion and the hardness of the film formed by the photosensitive resin composition are better.

Based on the above, since the photosensitive resin composition of the invention contains an alkali-soluble resin having an aromatic structure having fluorine and a specific structure and the hyperbranched polymer (D), the issue of lateral etching can be effectively alleviated, the affinity between the black matrix and a substrate can be increased, and the crosslink density in the black matrix can be increased at the same time. Therefore, the photosensitive resin composition of the invention has both the characteristics of good adhesion and good hardness, and is suitable for the manufacture of a black matrix of a color filter.

Although the invention has been described with reference to the above embodiments, it will be apparent to one of the ordinary skill in the art that modifications to the described embodiments may be made without departing from the spirit of the invention. Accordingly, the scope of the invention is defined by the attached claims not by the above detailed descriptions.

What is claimed is:

1. A photosensitive resin composition for a black matrix, comprising:
an alkali-soluble resin (A);
a compound (B) having an ethylenically unsaturated group;
a photoinitiator (C);
a hyperbranched polymer (D);
a solvent (E); and
a black pigment (F),
wherein the alkali-soluble resin (A) comprises a first alkali-soluble resin (A-1) represented by formula (1), 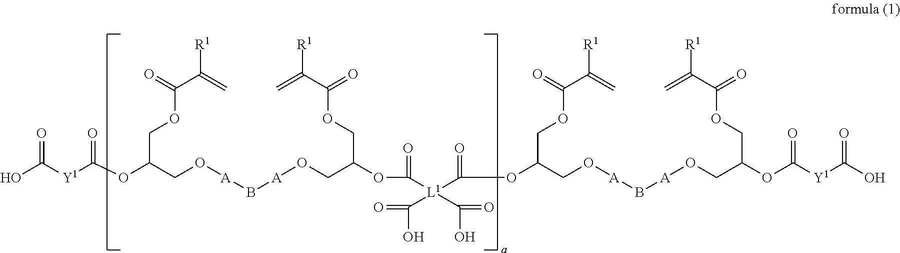
in formula (1), A represents a phenylene group or a phenylene group having a substituent, wherein the substituent is a C₁ to C₅ alkyl group, a halogen atom, or a phenyl group; B represents —CO—, —SO₂—, —C(CF₃)₂—, —Si(CH₃)₂—, —CH₂—, —C(CH₃)₂—, —O—, 9,9-fluorenylidene, or a single bond; L¹ represents a tetravalent carboxylic acid residue containing a fluorine atom or a tetravalent carboxylic acid residue without a fluorine atom; Y¹ represents a divalent carboxylic acid residue containing a fluorine atom or a divalent carboxylic acid residue without a fluorine atom; R¹ represents a hydrogen atom or a methyl group; a represents an integer of 1 to 20; and at least one of L′ and Y′ contains a fluorine atom;
the hyperbranched polymer (D) is formed by reacting a multi-mercapto compound represented by formula (II) and a multi-functional (meth)acrylate represented by formula (I), 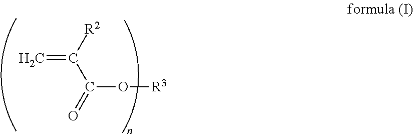
in formula (I), R² represents a hydrogen atom or a C₁ to C₄ alkyl group;
R³ represents a residual group after an esterification of an n number of hydroxyl groups in a hydroxyl group-containing compound having an m number of hydroxyl groups, wherein m≧n, and n represents an integer of 2 to 20,
the hydroxyl group-containing compound is R⁴(OH)ₘ or a compound in which the R⁴(OH)ₘ is modified by propylene oxide, epichlorohydrin, an alkyl group, an alkoxy group, or hydroxypropyl acrylate,
R⁴(OH)ₘ is a C₂ to C₁₈ polyalcohol, polyhydric alcohol ether formed by the polyalcohol, an ester formed by reacting the polyalcohol and an acid, or silicone, 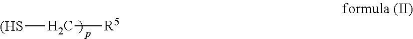
in formula (II), R⁵ represents a single bond, a C₁ hydrocarbon group, or a C₂ to C₂₂ straight-chain or branched-chain hydrocarbon group, and a skeleton of R⁵ may further comprise a sulfur atom or an oxygen atom formed in an ester group,
p represents an integer of 2 to 6, wherein in the case that R⁵ represents a single bond, p represents 2; in the case that R⁵ represents a C₁ hydrocarbon group, p represents an integer of 2 to 4; and in the case that R⁵ represents a C₂ to C₂₂ straight-chain or branched-chain hydrocarbon group, p represents an integer of 2 to 6.

2. The photosensitive resin composition for a black matrix of claim 1, wherein in the hyperbranched polymer (D), an addition molar ratio of a mercapto group of the multi-mercapto compound represented by formula (II) with respect to a carbon-carbon double bond of the multi-functional (meth)acrylate represented by formula (I) is 1/200 to 1/2.

3. The photosensitive resin composition for a black matrix of claim 1, wherein the hyperbranched polymer (D) is formed by reacting a remaining (meth)acrylate group from a reaction of the multi-mercapto compound represented by formula (II) and the multi-functional (meth)acrylate represented by formula (I) with a mercapto compound having a carboxyl group represented by formula (III),
HS—R⁶OOH)_{q} formula (III)
in formula (III), R⁶ represents a C₁ to C₁₂ alkylene group and q represents an integer of 1 to 3.

4. The photosensitive resin composition for a black matrix of claim 3, wherein in the hyperbranched polymer (D), an addition molar ratio of a mercapto group of the multi-mercapto compound represented by formula (II) and the mercapto compound having a carboxyl group represented by formula (III) with respect to a carbon-carbon double bond of the multi-functional (meth)acrylate represented by formula (I) is 1/200 to 1/2.

5. The photosensitive resin composition for a black matrix of claim 1, wherein the first alkali-soluble resin (A-1) represented by formula (1) is obtained by reacting a first mixture, the first mixture comprising:
a diol compound (a-1) containing a polymeric unsaturated group;
a tetracarboxylic acid or an acid dianhydride thereof (a-2); and
a dicarboxylic acid or an acid anhydride thereof (a-3),
wherein the tetracarboxylic acid or an acid dianhydride thereof (a-2) comprises a tetracarboxylic acid or an acid dianhydride thereof (a-2-1) containing a fluorine atom, other tetracarboxylic acids or an acid dianhydride thereof (a-2-2) other than the tetracarboxylic acid or an acid dianhydride thereof (a-2-1) containing a fluorine atom, or a combination of the two;
the dicarboxylic acid or an acid anhydride thereof (a-3) comprises a dicarboxylic acid or an acid anhydride thereof (a-3-1) containing a fluorine atom, other dicarboxylic acids or an acid anhydride thereof (a-3-2) other than the dicarboxylic acid or an acid anhydride thereof (a-3-1) containing a fluorine atom, or a combination of the two;
at least one of the tetracarboxylic acid or an acid dianhydride thereof (a-2) and the dicarboxylic acid or an acid anhydride thereof (a-3) contains a fluorine atom.

6. The photosensitive resin composition for a black matrix of claim 5, wherein the tetracarboxylic acid or an acid dianhydride thereof (a-2-1) containing a fluorine atom is selected from the group consisting of a tetracarboxylic acid compound containing a fluorine atom represented by formula (2-1) and a tetracarboxylic acid dianhydride compound containing a fluorine atom represented by formula (2-2), 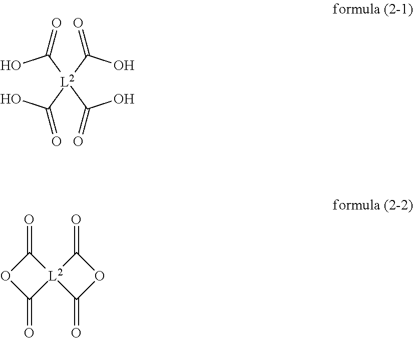
in formula (2-1) and formula (2-2), L² is selected from one of the groups represented by formula (L-1) to formula (L-6), 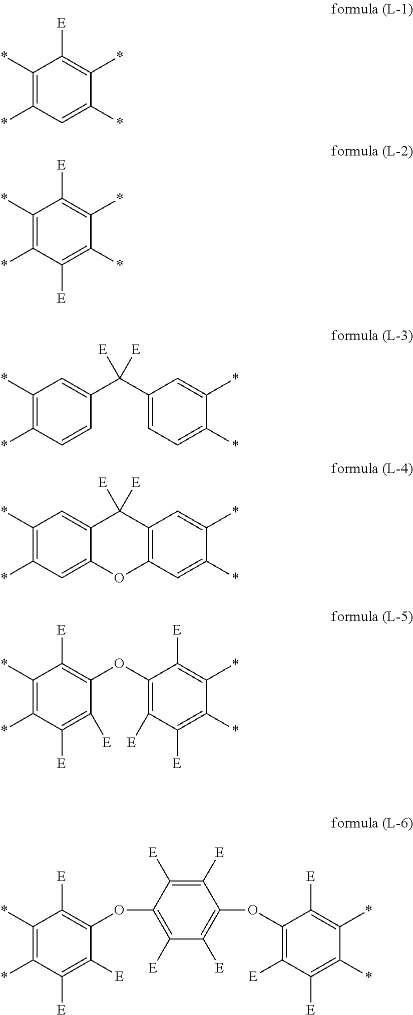
in formula (L-1) to formula (L-6), E each independently represents a fluorine atom or a trifluoromethyl group, and * represents the location of bonding with a carbon atom.

7. The photosensitive resin composition for a black matrix of claim 5, wherein the dicarboxylic acid or an acid anhydride thereof (a-3-1) containing a fluorine atom is selected from the group consisting of a dicarboxylic acid compound containing a fluorine atom represented by formula (3-1) and a dicarboxylic acid anhydride compound containing a fluorine atom represented by formula (3-2), 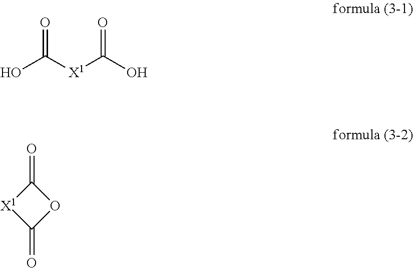
in formula (3-1) and formula (3-2), X¹ represents a C₁ to C₁₀₀ organic group containing a fluorine atom.

8. The photosensitive resin composition for a black matrix of claim 5, wherein a number of moles of the diol compound (a-1) containing a polymeric unsaturated group, a number of moles of the tetracarboxylic acid or an acid dianhydride thereof (a-2-1) containing a fluorine atom, and a number of moles of the dicarboxylic acid or an acid anhydride thereof (a-3-1) containing a fluorine atom satisfy a relationship [(a-2-1)+(a-3-1)]/(a-1)=0.4-1.6.

9. The photosensitive resin composition for a black matrix of claim 1, wherein based on a usage amount of 100 parts by weight of the alkali-soluble resin (A), a usage amount of the first alkali-soluble resin (A-1) is 10 parts by weight to 100 parts by weight, a usage amount of the compound (B) having an ethylenically unsaturated group is 15 parts by weight to 200 parts by weight, a usage amount of the photoinitiator (C) is 5 parts by weight to 55 parts by weight, a usage amount of the hyperbranched polymer (D) is 3 parts by weight to 35 parts by weight, a usage amount of the solvent (E) is 1000 parts by weight to 5000 parts by weight, and a usage amount of the black pigment (F) is 60 parts by weight to 600 parts by weight.

10. The photosensitive resin composition for a black matrix of claim 1, wherein the compound (B) having an ethylenically unsaturated group comprises a compound (B-1) having an acidic group and at least three ethylenically unsaturated groups.

11. The photosensitive resin composition for a black matrix of claim 10, wherein based on a usage amount of 100 parts by weight of the alkali-soluble resin (A), a usage amount of the compound (B-1) having an acidic group and at least three ethylenically unsaturated groups is 15 parts by weight to 150 parts by weight.

12. A method for manufacturing a color filter, comprising forming a black matrix by using the photosensitive resin composition for a black matrix of claim 1.

13. A black matrix made of the photosensitive resin composition for a black matrix of claim 1.

14. A color filter, comprising the black matrix of claim 13.

15. A liquid crystal display apparatus, comprising the color filter of claim 14.
